(19) United States
(12) Patent Application Publication
(10) Pub. No.: US 2009/0309153 A1
(43) Pub. Date: Dec. 17, 2009

(54) METHOD OF MANUFACTURING SEMICONDUCTOR DEVICE AND SEMICONDUCTOR DEVICE

(75) Inventors: Itaru YANAGI, Kunitachi (JP); Digh Hisamoto, Kokubunji (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/481,570

(22) Filed: Jun. 9, 2009

(30) Foreign Application Priority Data
Jun. 13, 2008 (JP) JP2008-154821

(51) Int. Cl. H01L 29/792; H01L 21/336

(52) U.S. Cl. 257/324; 438/261; 257/E29.309; 438/287; 257/E21.409

(57) ABSTRACT

A process of forming a non-volatile memory in a memory region on a silicon substrate, in which a select gate electrode is formed on a main surface of the silicon substrate, and a dummy gate adjacent to one of sidewall surfaces of the electrode is formed. Then, memory source/drain regions are formed by ion implantation using the dummy gate as an ion implantation mask. Then, the dummy gate is removed, and a charge accumulating film and a memory gate electrode are sequentially formed at the part where the dummy gate has been provided, thereby forming a structure in which the memory source/drain regions are arranged at portions below and lateral to the memory gate electrode. In this process, the charge accumulating film and the memory gate electrode are formed after the ion implantation for forming the memory source/drain regions is carried out.

### CROSS-REFERENCE TO RELATED APPLICATION

The present application claims priority from Japanese Patent Application No. JP 2008-154821 filed on Jun. 13, 2008, the content of which is hereby incorporated by reference into this application.

### TECHNICAL FIELD OF THE INVENTION

The present invention relates to semiconductor device techniques and particularly relates to a method for effectively operating the semiconductor devices having a non-volatile memory structure.

### BACKGROUND OF THE INVENTION

Currently, large scale integrated circuits (LSIs) in which semiconductor elements are integrated are used in control of various systems and becoming one of the infrastructures which support the society. Since operation of present-day LSIs is based on carrying out computing processing in accordance with programs, the capability to store the programs is an essential condition in many cases. As an element for the condition, a non-volatile semiconductor storage device (non-volatile memory), which is one of integrated semiconductor memories built in an LSI, has become extremely important. Moreover, in order to use the LSI for various devices, the non-volatile memory is required to be able to restructure the stored programs. In this manner, the non-volatile memory which is rewritable and able to keep the stored information even when power of the LSI is turned off is essential.

Regarding a non-volatile memory of a semiconductor element, for example, descriptions about a non-volatile memory of a so-called floating gate type and a non-volatile memory using an insulating film can be found in S. Sze, “Physics of Semiconductor Devices”, 2nd edition, Wiley-Interscience pub., p. 496-506 (Non-Patent Document 1). Particularly, there is a non-volatile memory which stores information by stacking insulating films and accumulating electric charges at a trapping level, etc. in the interface or inside the insulating film. Such a non-volatile memory does not require formation of a new conductive layer compared with the floating gate type, and it is known that the non-volatile memory can be formed with good conformity with the CMOS (Complementary Metal Oxide Semiconductor) LSI processes.

The insulating film that accumulates electric charges has been widely used from the past since both the retention characteristic of electric charges and the rewriting durability can be achieved by stacking a nitride film and an oxide film. For example, as an example of pioneering development, there is a report by Yatsuda et al., “IEEE Transaction on Electron Devices”, VOL. ED-32, No. 2, pp. 224-231, 1985 (Non-Patent Document 2). In this report, a two-transistor cell in which a memory transistor and a select transistor are disposed in series is used. In the memory transistor, injection/release of electric charges is caused on the entire surface of a channel by using the F-N (Fowler-Nordheim) tunneling current and a direct tunneling current by biasing between the channel and a gate.

Also, there has been proposed a memory cell which carries out memory operation by combining two transistors, which are different from the above-described method of Yatsuda et al., instead of one memory transistor. About this operation, descriptions can be found, for example, in “1997 Symposium on VLSI Technology”, p. 63-64 (Non-Patent Document 3). In this structure, a polycrystalline silicon gate to cause the memory operation (hereinafter, a memory gate electrode) and a gate to select a memory cell (hereinafter, a select gate electrode (also referred to as a control gate electrode)) are separately formed. Moreover, similar descriptions can be also found, for example, in U.S. Pat. No. 5,969,383 (Patent Document 1) and U.S. Pat. No. 6,477,084 (Patent Document 2), and it is sometimes referred to as a split gate structure.

About writing operation in the non-volatile memory having the split gate structure as described above, for example, descriptions can be found in A. T. Wu et al., “1986 IEEE International Electron Device Meeting, Technical Digest”, p. 584-587 (Non-Patent Document 4). Moreover, about erasing operation in the non-volatile memory having the split gate structure as described above, for example, descriptions can be found T. Y. Chan et al., “1987 IEEE International Electron Device Meeting, Technical Digest”, p. 718-721 (Non-Patent Document 5).

Moreover, for example, Japanese Patent Application Laid-Open Publication No. 2002-289715 (Patent Document 3) discloses techniques about a production method of a twin MONOS (Metal-Oxide-Nitride-Oxide Semiconductor (Silicon)) memory cell array, which is a structure similar to that of the split gate type memory.

### SUMMARY OF THE INVENTION

The inventors of the present invention have studied and found out the following problems about the non-volatile memory of the split gate structure as described above.

The steps of forming the non-volatile memory of the split gate structure on a semiconductor substrate include a step of forming source/drain regions by subjecting the semiconductor substrate to ion implantation. In this step, according to the manufacturing step studied by the present inventors, the ion implantation is carried out while using two gate electrodes (select gate electrode, memory gate electrode) as an ion implantation mask, thereby forming the source/drain regions.

However, it has been found out that the ion implantation step using the gate electrodes as the ion implantation mask can damage a charge accumulating film, and, as a result, it has been elucidated that the step is a cause that interferes improvement of the characteristics of the non-volatile memory.

In the non-volatile memory of the split gate type studied by the present inventors, a stacked insulating film for accumulating charges is disposed between the memory gate electrode and the semiconductor substrate. When the semiconductor substrate is subjected to the ion implantation by using the memory gate electrode as the ion implantation mask, impurity ions permeate through the memory gate electrode reaching the charge accumulating film, so that the charge accumulating film is damaged.

Particularly, as the gate length of a transistor has been shortened along with recent scaling (downsizing) of an LSI, it is desirable to also lower the heights of the select gate electrode and the memory gate electrode in terms of stability of processing. Under these circumstances, the damage on the charge accumulating film caused by ion implantation is increased further.

Such damage on the charge accumulating film caused by the ion implantation, particularly, the damage onto a barrier insulating film which is disposed on the interface of an electrode and a substrate in order to prevent leakage of charges accelerates the leakage of the retained charges to the electrode or the substrate. As a result, in the non-volatile memory of the split gate type, it has become difficult to improve characteristics such as data retention characteristics and reliability of the memory operation.

Therefore, it is an object of the present invention to provide techniques that improve characteristics of a semiconductor device having a non-volatile memory.

The above and other objects and novel characteristics of the present invention will be apparent from the description of the present specification and the accompanying drawings.

The present application discloses a plurality of elements of the invention, and the summary of an embodiment among them will be briefly described below.

A process of forming a non-volatile memory in a first region on a semiconductor substrate, in which, after a first gate electrode is formed on a main surface of the semiconductor substrate via a first gate insulating film, a dummy gate arranged to be adjacent to one of sidewall surfaces of the first gate electrode is formed, and a first semiconductor region is formed in the semiconductor substrate at a portion below and lateral to the dummy gate. In this step, the first semiconductor region is formed by ion implantation using the dummy gate as an ion implantation mask. Then, the dummy gate is removed, and a charge accumulating film and a second gate electrode are sequentially formed at the part where the dummy gate has been arranged, thereby forming a structure in which the first semiconductor region is arranged at the portion below and lateral to the second gate electrode. In this process, the charge accumulating film and the second gate electrode are formed after the ion implantation for forming the first semiconductor region is carried out.

A typical effect of one embodiment described above among the plurality of inventions disclosed in the present application will be briefly described as follows.

That is, performance of a non-volatile semiconductor storage device can be improved.

### BRIEF DESCRIPTIONS OF THE DRAWINGS

FIG. 1 is an equivalent circuit diagram of a non-volatile memory studied by the inventors of the present invention;

FIG. 2 is a plan view of the non-volatile memory corresponding to the circuit shown in FIG. 1;

FIG. 3 is a cross-sectional view of the non-volatile memory corresponding to the circuit shown in FIG. 1, which is a cross-sectional view of main parts taken along the line Xa-Xa of FIG. 2;

FIG. 4 is a circuit diagram of an example of a configuration in which a memory cell array is formed by using the non-volatile memory of FIG. 1 to FIG. 3;

FIG. 5 is an explanatory diagram illustrating a representative write operation of the non-volatile memory of FIG. 1 to FIG. 3;

FIG. 6 is an explanatory diagram illustrating a representative erase operation of the non-volatile memory of FIG. 1 to FIG. 3;

FIG. 7 illustrates cross-sectional views of main parts during a manufacturing process of a semiconductor device studied by the present inventors, wherein the cross-sectional view taken along the line Xa-Xa of FIG. 2 is illustrated on the left, and the cross-sectional view taken along the line Ya-Ya of FIG. 2 is illustrated on the right;

FIG. 8 illustrates cross-sectional views of main parts of the semiconductor device during the manufacturing process continued from FIG. 7;

FIG. 9 illustrates cross-sectional views of main parts of the semiconductor device during the manufacturing process continued from FIG. 8;

FIG. 10 illustrates cross-sectional views of main parts of the semiconductor device during the manufacturing process continued from FIG. 9;

FIG. 11 illustrates cross-sectional views of main parts of the semiconductor device during the manufacturing process continued from FIG. 10;

FIG. 12 illustrates cross-sectional views of main parts during a manufacturing process of the semiconductor device which is the first embodiment of the present invention, wherein the cross-sectional view of main parts of a non-volatile memory during the manufacturing process is illustrated on the left, and the cross-sectional view of main parts of peripheral circuit elements during the manufacturing step is illustrated on the right;

FIG. 13 illustrates cross-sectional views of main parts during another manufacturing process of a semiconductor device which is a first embodiment of the present invention, wherein the cross-sectional view of main parts of a non-volatile memory during the manufacturing process is illustrated on the left, and the cross-sectional view of main parts of peripheral circuit elements during the manufacturing process is illustrated on the right;

FIG. 14 illustrates cross-sectional views of main parts of the semiconductor device during the manufacturing process continued from FIG. 13;

FIG. 15 illustrates cross-sectional views of main parts of the semiconductor device during the manufacturing process continued from FIG. 14;

FIG. 16 illustrates cross-sectional views of main parts of the semiconductor device during the manufacturing process continued from FIG. 15;

FIG. 17 illustrates cross-sectional views of main parts of the semiconductor device during the manufacturing process continued from FIG. 12 or FIG. 16;

FIG. 18 illustrates cross-sectional views of main parts of the semiconductor device during the manufacturing process continued from FIG. 17;

FIG. 19 illustrates cross-sectional views of main parts of the semiconductor device during the manufacturing process continued from FIG. 18;

FIG. 20 illustrates cross-sectional views of main parts of the semiconductor device during the manufacturing process continued from FIG. 19;

FIG. 21 illustrates cross-sectional views of main parts of the semiconductor device during the manufacturing process continued from FIG. 20;

FIG. 22 illustrates cross-sectional views of main parts of the semiconductor device during the manufacturing process continued from FIG. 21;

FIG. 23 illustrates cross-sectional views of main parts of the semiconductor device during the manufacturing process continued from FIG. 22;

FIG. 24 illustrates cross-sectional views of main parts of the semiconductor device during the manufacturing process continued from FIG. 23;

FIG. 25 illustrates cross-sectional views of main parts of the semiconductor device during the manufacturing process continued from FIG. 24;

FIG. 26 illustrates cross-sectional views of main parts of the semiconductor device during the manufacturing process continued from FIG. 25;

FIG. 27 is a plan view of an SRAM circuit formed in a peripheral circuit region of a semiconductor device which is a second embodiment of the present invention;

FIG. 28 illustrates cross-sectional views of main parts during a manufacturing process of a semiconductor device which is the second embodiment of the present invention, wherein the cross-sectional view of main parts of a non-volatile memory during the manufacturing process is illustrated on the left, and the cross-sectional views of main parts of peripheral circuit elements taken along the line P1-P1 and the line P2-P2 of FIG. 27, respectively, during the manufacturing process are illustrated on the right;

FIG. 29 illustrates cross-sectional views of main parts of the semiconductor device during the manufacturing process continued from FIG. 28;

FIG. 30 illustrates cross-sectional views of main parts of the semiconductor device during the manufacturing process continued from FIG. 29;

FIG. 31 illustrates cross-sectional views of main parts of the semiconductor device during the manufacturing process continued from FIG. 30;

FIG. 32 illustrates cross-sectional views of main parts of the semiconductor device during the manufacturing process continued from FIG. 31;

FIG. 33 illustrates cross-sectional views of main parts of the semiconductor device during the manufacturing process continued from FIG. 32;

FIG. 34 illustrates cross-sectional views of main parts of the semiconductor device during the manufacturing process continued from FIG. 33;

FIG. 35 illustrates cross-sectional views of main parts of the semiconductor device during the manufacturing process continued from FIG. 34;

FIG. 36 illustrates cross-sectional views of main parts of the semiconductor device during the manufacturing process continued from FIG. 35;

FIG. 37 illustrates cross-sectional views of main parts during a manufacturing process of a semiconductor device which is a third embodiment of the present invention, wherein the cross-sectional view of main parts of a non-volatile memory during the manufacturing process is illustrated on the left, and the cross-sectional views of main parts of peripheral circuit elements taken along the line P1-P1 and the line P2-P2 of FIG. 27, respectively, during the manufacturing process are illustrated on the right;

FIG. 38 illustrates cross-sectional views of main parts of the semiconductor device during the manufacturing process continued from FIG. 37;

FIG. 39 illustrates cross-sectional views of main parts of the semiconductor device during the manufacturing process continued from FIG. 38;

FIG. 40 illustrates cross-sectional views of main parts of the semiconductor device during the manufacturing process continued from FIG. 39;

FIG. 41 illustrates cross-sectional views of main parts of the semiconductor device during the manufacturing process continued from FIG. 40;

FIG. 42 illustrates cross-sectional views of main parts of the semiconductor device during the manufacturing process continued from FIG. 41;

FIG. 43 illustrates cross-sectional views of main parts of the semiconductor device during the manufacturing process continued from FIG. 42;

FIG. 44 is a cross-sectional view of a semiconductor device in a manufacturing process which is a fourth embodiment of the present invention continued from FIG. 23;

FIG. 45 illustrates cross-sectional views of main parts of the semiconductor device during the manufacturing process continued from FIG. 44; and

FIG. 46 illustrates cross-sectional views of main parts of the semiconductor device during the manufacturing process continued from FIG. 45.

### DESCRIPTIONS OF THE PREFERRED EMBODIMENTS

Components having the same function are denoted by the same reference symbols throughout the drawings for describing the embodiments, and the repetitive description thereof will be omitted as much as possible. In the following, embodiments of the present invention will be described in detail with reference to the accompanying drawings.

### First Embodiment

First, a configuration of a non-volatile memory of a split gate type which has been studied by the inventors of the present invention and problems found in a manufacturing process of the non-volatile memory will be described in detail.

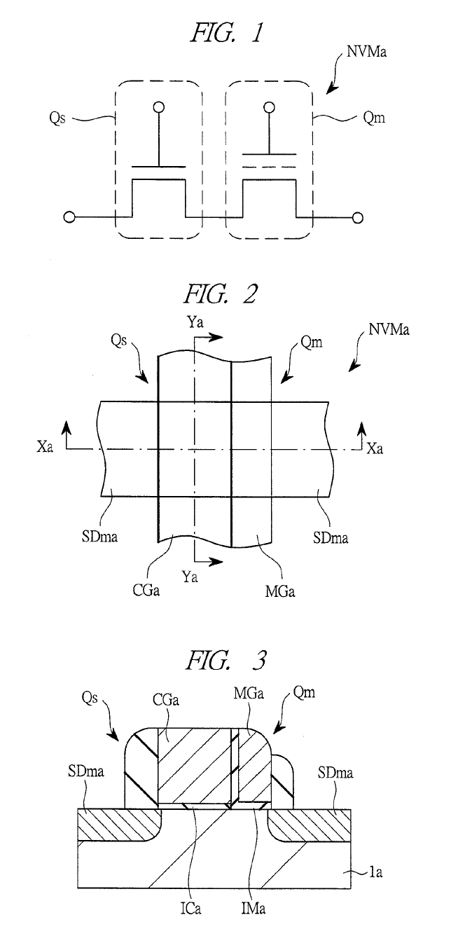

The non-volatile memory of the split gate type studied by the present inventors basically has two MIS transistors which are based on the n-channel type MIS (Metal Insulator Semiconductor) field effect transistors (FETs) (hereinafter, simply called n-type MIS transistor). More specifically, a select transistor and a memory transistor next the select transistor are structured so as to be coupled to each other in a so-called “vertically stacked” arrangement. This is illustrated as an equivalent circuit in FIG. 1. FIG. 2 and FIG. 3 illustrate, as an example, a plan view of a memory element corresponding to the circuit shown in FIG. 1 and a cross-sectional view taken along the Xa-Xa line of FIG. 2, respectively.

This non-volatile memory NVMa has the select transistor Qs and the memory transistor Qm. The select transistor Qs and the memory transistor Qm are electrically connected to each other in series.

A select gate electrode CGa of the select transistor Qs is formed of, for example, low-resistance polycrystalline silicon (polysilicon) and is formed on a main surface of a silicon substrate 1a via a select gate insulating film ICa. The select gate insulating film ICa is formed of, for example, a silicon oxide film. On the other hand, a memory gate electrode MGa of the memory transistor Qm is formed of, for example, low-resistance polycrystalline silicon and is formed on the main surface of the silicon substrate 1a and on a side surface of the select gate electrode CGa via a charge accumulating film IMa. The charge accumulating film IMa has a so-called MONOS structure, in which silicon nitride film is sandwiched by silicon oxide films, and is a stacked insulating film, which plays a role of electric charge retention. The memory gate electrode MGa can be effectively formed by using a process called spacer. The formation method thereof will be described in detail later.

Also, on the main surface of the silicon substrate la, memory source/drain regions SDma are formed on one side of the select gate electrode CGa and on one side of the memory gate electrode MGa, respectively. The memory source/drain regions SDma are semiconductor regions having a conduction type that is opposite to that of the silicon substrate la. Note that the memory source/drain regions SDma may have a so-called LDD (Lightly Doped Drain) structure, which has an extension region having a lower impurity concentration.

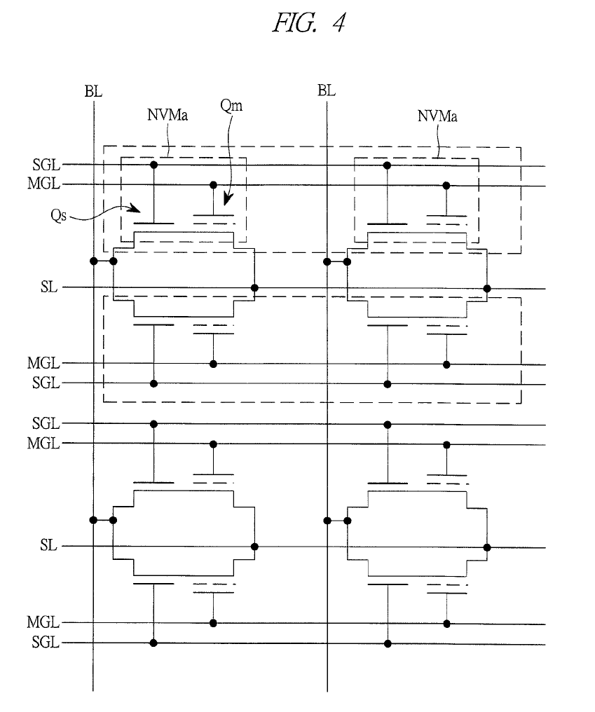

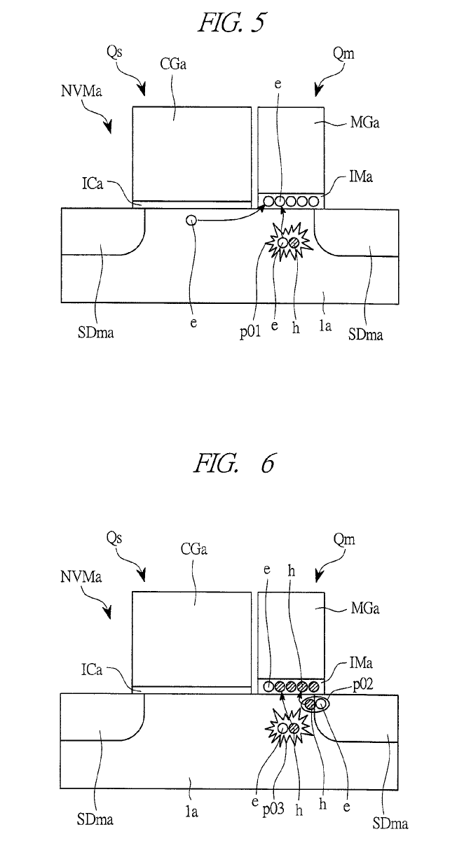

An arrangement configuration example of the case in which an array is formed with using such a non-volatile memory NVMa is illustrated in FIG. 4. The select gate electrodes CGa of the select transistors Qs constitute word lines SGL, and the memory gate electrodes MGa of the memory transistors Qm constitute word lines MGL. The memory source/drain regions SDma of the select transistor Qs-side serve as bit lines BL, and the memory source/drain regions SDma of the memory transistor Qm-side serve as source lines SL.

FIG. 5 and FIG. 6 illustrate explanatory drawings for explaining representative writing/erasing operations of the non-volatile memory NVMa. Four states, i.e., write, erase, retention, and read are considered as basic operations of the non-volatile memory NVMa. However, the names of the four states are used as representative ones, and the names of write and erase are exchangeable with each other. Also, a typical operation will be described; however, various different operation methods may be considered. The non-volatile memory NVMa composed of n-type MIS transistors will be described here for explanation; however, the memory which is composed of p-channel-type MIS transistors (hereinafter, simply, p-type MIS transistors) can be similarly described in principle.

The write operation of the non-volatile memory NVMa will be described with reference to FIG. 5. In the write operation, a positive potential is applied to the memory source/drain region SDma of the memory transistor Qm-side, and a ground potential, which is the same as that of the silicon substrate 1a, is applied to the memory source/drain region SDma of the select transistor Qs-side. In this state, a gate overdrive voltage, which is higher with respect to the silicon substrate 1a, is applied to the memory gate electrode MGa, thereby strongly inverting a channel below the memory gate electrode MGa and causing the memory transistor Qm to be in an On state. At this point, a voltage that is higher than the threshold voltage of the select transistor Qs by about 0.1 to 0.2 V is applied to the select gate electrode CGa, thereby also causing the select transistor Qs to be in an On state.

At this point, a strongest electric field is generated in the vicinity of the boundary of the two gate electrodes CGa and MGa. As a result, many hot electrons are generated and injected to the memory gate electrode MGa-side. In the drawing, a state of generation of charge carriers generated by impact ionization is shown in a main part p01. White circular marks represent electrons “e”, and hatched circular marks represent positive holes “h”. This phenomenon is referred to as source side injection (SSI), and a description thereof can be found in above-mentioned Non-Patent Document 4. In the description therein, a floating gate type memory cell is used; however, the injection mechanism is similar also in the MONOS type using the charge accumulating film IMa like the present non-volatile memory NVMa.

As a characteristic of the hot electron injection of the above-described method, the electric field is concentrated in the vicinity of the boundary of the select gate electrode CGa and the memory gate electrode MGa; therefore, the carriers are intensively injected to an end portion of the memory gate electrode MGa on the select gate electrode CGa-side. In the floating gate type, a charge retaining layer is configured by an electrode. However, in the MONOS type, the carriers are retained in an extremely narrow region since the carriers are accumulated in the charge accumulating film IMa which is a stacked insulating film.

The erase operation of the non-volatile memory NVMa will be described with reference to FIG. 6. In the erase operation, a negative potential is applied to the memory gate electrode MGa, and a positive potential is applied to the memory source/drain region SDma of the memory transistor Qm-side. As a result, strong inversion occurs in the region that is planarly overlapped with the memory gate electrode MGa in an end portion of the memory source/drain region SDma. At this point, an interband tunneling (Band to Band Tunneling: BTBT) phenomenon occurs, and positive holes h are generated. In the drawing, a state of the BTBT phenomenon is shown in a main part p02. A description about the BTBT phenomenon can be found in the above-mentioned Non-Patent Document 5. In the present non-volatile memory NVMa, the generated positive holes h are accelerated in the channel direction, attracted by the bias of the memory gate electrode MGa, and injected into the charge accumulating film IMa, thereby carrying out the erase operation.

Also, a state in which secondary electron-hole pairs are generated by the positive holes h generated by the BTBT phenomenon is illustrated in a main part p03 in the drawing. These carriers can be also injected into the charge accumulating film IMa. In other words, the threshold voltage of the memory transistor Qm increased by the electric charge of the electrons e can be lowered by the electric charge of the injected positive holes h.

Upon retention, the electric charge is retained as the electric charge of the carriers injected into the charge accumulating film IMa. Movement of the carriers in the charge accumulating film IMa, which is a stacked insulating film, is extremely small and slow. Therefore, even when no voltage is applied to the memory gate electrode MGa, the electric charge is retained.

Upon reading, a positive potential is applied to the memory source/drain region SDma of the select transistor Qs-side, and a positive potential is applied to the select gate electrode CGa, thereby causing the channel below the select gate electrode CGa to be strongly inverted and causing the select transistor Qs to be in an On state. In this state, a potential at a level that is capable of discriminating a threshold voltage difference of the memory transistor Qm which is given by the written or erased state (i.e., an intermediate potential between the threshold voltage of the written state and the threshold voltage of the erased state) is applied to the memory gate electrode MGa. As a result, the retained electric charge information can be read as current.

As a normal manufacturing method of the split gate type non-volatile memory NVMa, first, the select gate electrode CGa is processed. Subsequently, the memory gate electrode MGa is formed like a spacer on a sidewall of the select gate electrode CGa by using a process referred to as spacer. Thereafter, it is effective that the silicon substrate 1a is subjected to ion implantation by using the select gate electrode CGa and the memory gate electrode MGa as an ion implantation mask, thereby forming the memory source/drain regions SDma. Details of the manufacturing method will be described below.

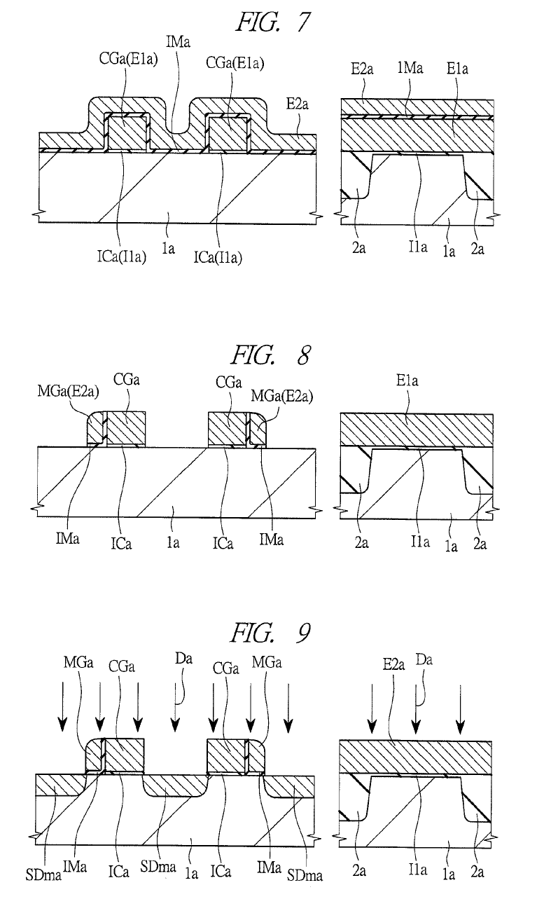

A manufacturing process of a semiconductor device having the split gate type non-volatile memories NVMa studied by the present inventors will be described with reference to FIG. 7 to FIG. 11. In the respective drawings, cross-sectional views viewed in the direction of the arrow along the line Xa-Xa of FIG. 2 are illustrated on the left, and cross-sectional views viewed in the direction of the arrow along the line Ya-Ya are illustrated on the right. Also, in the formation process, a process corresponding to the so-called 0.13-micron generation will be used for description.

First, as shown in FIG. 7, isolation portions 2a for defining active regions are formed in the main surface of the silicon substrate 1a by using a known shallow trench isolation (STI) process. Then, a silicon surface is exposed in the active regions, and the substrate surface is oxidized by a thermal oxidation method, thereby forming a first insulating film I1a formed of a silicon oxide film having a thickness of about 2.5 nm. Subsequently, a first conductor film E1a formed of a polycrystalline silicon film having a thickness of about 200 nm is deposited by a chemical vapor deposition (CVD) method.

Then, the first conductor film E1a is processed, thereby forming the select gate electrodes CGa, which have been described with reference to above-described FIG. 2, FIG. 3, etc. In this process, although it is not illustrated herein, gate electrodes, etc. of a computing circuit part may be processed at the same time. Then, the first insulating film I1a is processed, thereby forming the select gate insulating film ICa.

Next, the charge accumulating film IMa is formed so as to cover the exposed of the silicon substrate 1a and a surface of the select gate electrodes CGa. As is described with reference to above-described FIG. 3, etc., the charge accumulating film IMa is the stacked insulating film having the function of accumulating charges and is formed in the following manner. First, a first silicon oxide film of about 4 nm is formed by carrying out oxidation. Subsequently, a first silicon nitride film of about 5 nm is deposited on the first silicon oxide film by the CVD method, and a second silicon oxide film of about 5 nm is formed on the first silicon nitride film by oxidation or the CVD method. The above-described stacked insulating film of the three layers has the function of accumulating electric charges and corresponds to the charge accumulating film IMa, which has been described with reference to above-described FIG. 3, etc.

Subsequently, a second conductor film E2a formed of a polycrystalline silicon film containing a p-type or n-type impurity at a high concentration is deposited so as to cover the charge accumulating film IMa. The second conductor film E2a is formed to have a thickness of about 80 nm by the CVD method or the like.

Next, as illustrated in FIG. 8, the entire surface of the second conductor film E2a is subjected to anisotropic etching. The step of subjecting the entire surface to anisotropy etching without using any etching mask in this manner is also referred to as an etch back step. As a result, the memory gate electrode MGa formed of the spacer-like second conductor film E2a is formed on a sidewall surface of each select gate electrode CGa so that the memory gate electrode MGa is arranged to be adjacent to the select gate electrode CGa via the charge accumulating film IMa. Moreover, although it is not illustrated here, additional etching may be carried out so as to remove unnecessary part of the second conductor film E2a remaining on sidewalls of similar projecting portions.

At the point when the above-described steps are finished, the memory gate electrodes MGa are formed on both sides of a pair of sidewall surfaces of the select gate electrode CGa. Herein, as is described by using above-described FIG. 3, FIG. 4, FIG. 5, etc., the memory gate electrode MGa can be formed on one side of the select gate electrode CGa as the constitution of the non-volatile memory NVMa. Therefore, in a subsequent step, one of the memory gate electrodes MGa formed on the both sidewall surfaces of the select gate electrode CGa is removed by additional etching. In this process, the charge accumulating film IMa made of a material different from that of the second conductor film E2a can be used as a base protecting film (etching stopper film).

Then, exposed part of the charge accumulating film IMa that is not covered by the memory gate electrode MGa is removed by etching. Subsequently, the surface of the silicon substrate 1a is cleaned and then thermally oxidized, thereby forming a silicon oxide film of about 2 nm (illustration is omitted in the drawing).

Next, as illustrated in FIG. 9, the silicon substrate la is subjected to ion implantation Da with using the select gate electrodes CGa and the memory gate electrodes MGa as an ion implantation mask, thereby forming the memory source/drain regions SDma. In the ion implantation Da, the silicon substrate 1a of the group IV is implanted with, for example, arsenic (As) ions of the group V. Therefore, the memory source/drain regions SDma are n-type (first conductive type) semiconductor regions.

Note that, in the present step, so-called extension regions may be formed by carrying out ion implantation having the acceleration energy and dose amount which are lower than those of the ion implantation Da. In that case, in a later step, sidewall spacers are formed on the sidewalls of the select gate electrode CGa and the memory gate electrode MGa, and then the above-described ion implantation Da is carried out with using them as an ion implantation mask, thereby forming the memory source/drain regions SDma.

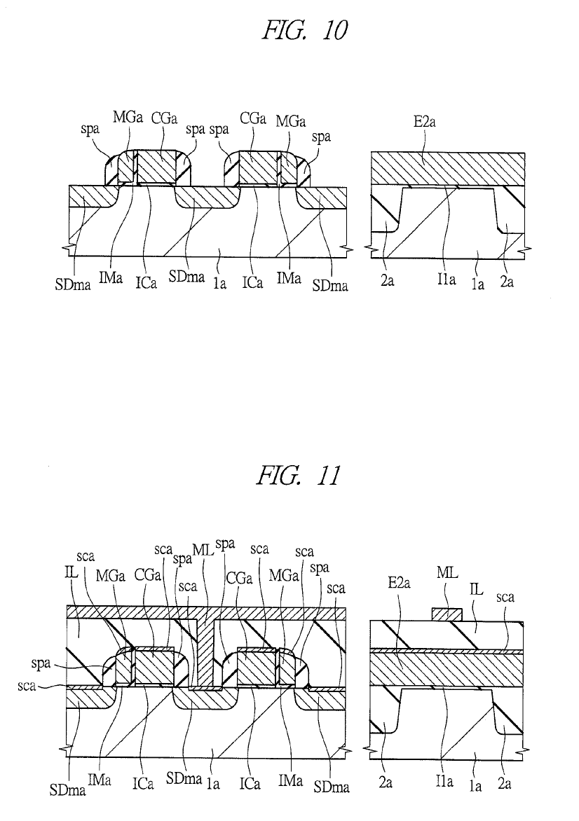

Next, as illustrated in FIG. 10, a silicon oxide film is formed so as to cover the silicon substrate 1a and the structure formed in the above-described steps, and the silicon oxide film is etched back, thereby forming sidewall spacers “spa” having spacer shapes which cover the sidewall surfaces of the select gate electrodes CGa and the memory gate electrodes MGa.

Next, as shown in FIG. 11, a metal silicide layer “sca” is formed on the select gate electrodes CGa, on the memory gate electrodes MGa, and on the memory source/drain regions SDma by a known salicide process. Subsequently, a metal wiring ML is formed in the interlayer insulating film IL by carrying out a wiring step of a normal CMOS process.

The manufacturing process of the non-volatile memory NvMa owned by the semiconductor device studied by the present inventors have been described above. In the above-described manner, the non-volatile memory NVMa of the split gate type can be formed on the silicon substrate 1a.

Meanwhile, further studies by the present inventors elucidated that the above-described manufacturing steps have the following problems. That is, the ion implantation Da described with reference to above-described FIG. 9 damages the charge accumulating film IMa below the memory gate electrodes MGa. This problem becomes more prominent as the height of the memory gate electrodes MGa is reduced for increasing performance by minimization of an LSI as mentioned above. Using the damaged charge accumulating film IMa in the non-volatile memory NVMa is a cause of interfering improvement of characteristics such as retention characteristics of charges and reliability.

Next, a manufacturing method of a semiconductor device of a present first embodiment and the semiconductor device of the present first embodiment formed by the manufacturing method will be described in detail with reference to FIG. 12 to FIG. 26. The manufacturing method of the semiconductor device of the present first embodiment includes a step of forming a non-volatile memory NVM in a memory region (first region) Rm on a silicon substrate (semiconductor substrate) 1. Moreover, the manufacturing method of the semiconductor device of the present first embodiment may have a step of forming peripheral circuit elements in a peripheral circuit region (second region) Rp on the silicon substrate 1. Hereinafter, the steps to which both the regions Rm and Rp are subjected will be described. On the left side of the drawings, cross-sectional views taken in the steps of forming the non-volatile memory NVM in the memory region Rm are illustrated. On the right side of the drawings, steps of forming MIS transistors Q1 as an example of the peripheral circuit elements in the peripheral circuit region Rp are illustrated. The cross-sectional views of the memory region Rm and the peripheral circuit region Rp illustrated in the same drawing are the cross-sectional views taken in the same step.

First, as shown in FIG. 12, isolation portions 2 are formed in a main surface of the silicon substrate 1 by using a known STI process so as to define active regions in which elements are to be fabricated. Then, in the peripheral circuit region Rp of the silicon substrate 1, a p-type impurity is implanted into a region in which an n-type MIS transistor is to be formed, and an n-type impurity is implanted into a region in which a p-type MIS transistor is to be formed, thereby defining the regions, respectively (not shown).

Then, thermal oxidation is carried out, thereby forming a first insulating film I1 of about 2.5 nm, which is an insulating film mainly formed of silicon oxide, on the main surface of the silicon substrate 1 in the memory region Rm and the peripheral circuit region Rp. Subsequently, a first conductor film E1 formed of a conductor film mainly made of polycrystalline silicon is formed on the main surface of the silicon substrate 1 in the memory region Rm and the peripheral circuit region Rp via the first insulating film I1.

In this process, first, the first conductor film E1 made of so-called undoped polycrystalline silicon not containing any predetermined impurity is formed. Subsequently, a photoresist film is formed on the silicon substrate 1, and the substrate is subjected to patterning by a photolithography method so that the peripheral circuit region Rp is covered. Then, an n-type impurity is ion-implanted into the first conductor film E1 of the memory region Rm while using the photoresist film as an ion implantation mask. Subsequently, by a similar method, in the peripheral circuit region Rp, the n-type impurity is ion-implanted into the first conductor film E1 in the region in which the n-type MIS transistor is to be formed, and the p-type impurity is ion-implanted into the first conductor film E1 in the region in which the p-type MIS transistor is to be formed. Thereafter, for example, the substrate is subjected to thermal treatment at 950° C. for about 120 seconds, thereby activating the impurities implanted into the first conductor film E1 formed of polycrystalline silicon.

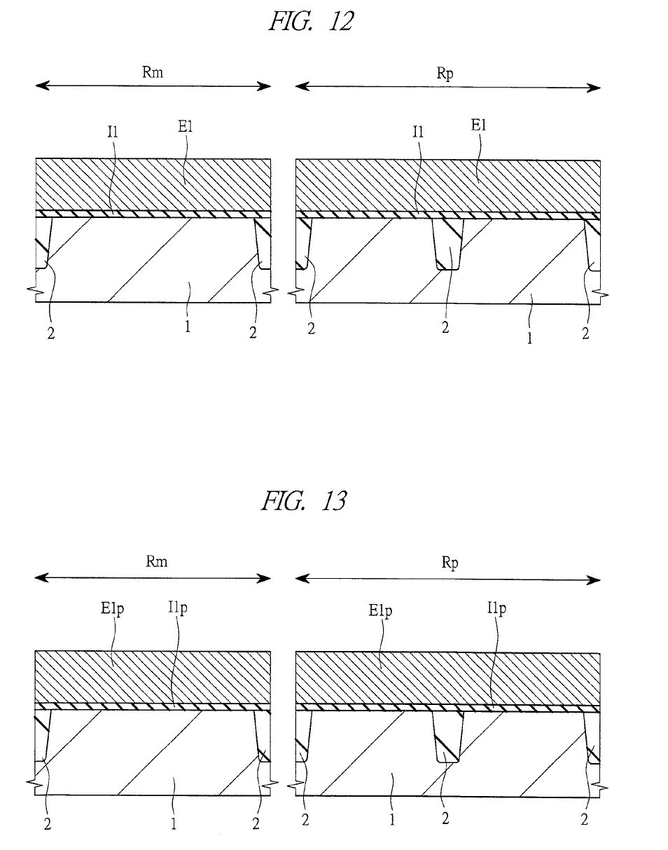

Note that the above-described step may be carried out in the following manner. First, as illustrated in FIG. 13, the isolation portions 2 are formed as same as above-described FIG. 12. Subsequently, on the main surface of the silicon substrate 1 in the memory region Rm and the peripheral circuit region Rp, a peripheral first insulating film (first insulating film) I1p formed of a silicon oxide film and a peripheral first conductor film (first conductor film) E1p formed of a polycrystalline silicon film are sequentially formed.

Next, as illustrated in FIG. 14, the peripheral first conductor film E1p and the peripheral first insulating film I1p of the memory region Rm are removed. This is carried out by, for example, covering the peripheral circuit region Rp by a photoresist film and carrying out dry etching while using the photoresist film as an etching mask.

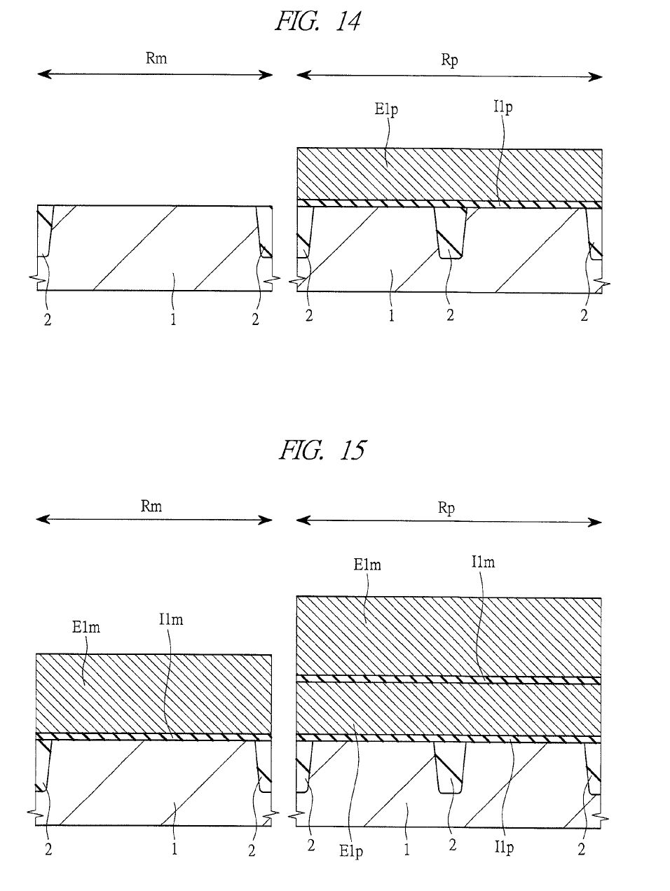

Next, as illustrated in FIG. 15, a memory first insulating film (first insulating film) I1m formed of a silicon oxide film and a memory first conductor film (first conductor film) E1m formed of a polycrystalline silicon film are sequentially formed on the main surface of the silicon substrate 1 in the memory region Rm and on the peripheral first conductor film E1p of the peripheral circuit region Rp.

Next, as illustrated in FIG. 16, the memory first conductor film E1m and the memory first insulating film I1m of the peripheral circuit region Rp are removed. This is carried out by, for example, covering the memory region Rm by a photoresist film and carrying out dry etching while using the photoresist film as an etching mask.

As described above, by the steps of FIG. 13 to FIG. 16, the first conductor film E1 formed of the memory first conductor film E1m and the first insulating film I1 formed of the memory first insulating film I1m are formed on the silicon substrate 1 in the memory region Rm, and the first conductor film E1 formed of the peripheral first conductor film E1p and the first insulating film I1 formed of the peripheral first insulating film I1p are formed on the silicon substrate 1 in the peripheral circuit region Rp. As a result, the first conductor film E1 or the first insulating film I1 can be formed having different film thicknesses on the memory region Rm and on the peripheral circuit region Rp, respectively. The first conductor film E1 and the first insulating film I1 are components which later serve as a gate electrode and a gate insulating film, and the gate electrode and the gate insulating film having different thicknesses depending on the regions can be formed by carrying out the steps described above. In the subsequent steps, description will be given below on the assumption that the thicknesses the gate electrode and the gate insulating are the same. Therefore, the above-described steps may be the step described in the above-described FIG. 12 or the steps described with reference to the above-described FIG. 13 to FIG. 16.

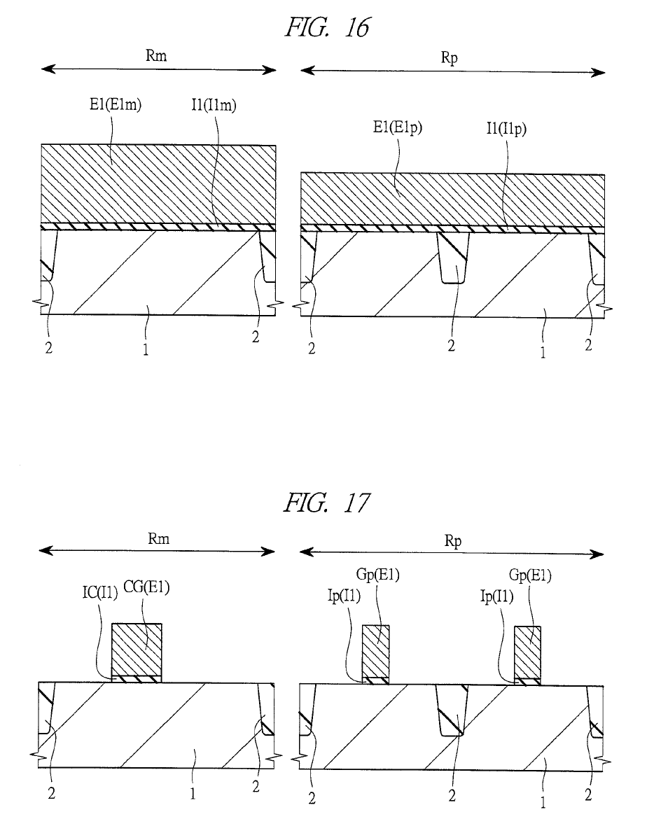

In a subsequent step, as illustrated in FIG. 17, the first conductor film E1 is processed to have desired gate patterns, thereby forming a select gate electrode (first gate electrode) CG formed of the first conductor film E1 in the memory region Rm and forming peripheral gate electrodes Gp formed of the first conductor film E1 in the peripheral circuit region Rp. In this process, an etching mask is formed by a known photolithography method (not shown), and anisotropic etching is carried out, thereby processing the respective gate patterns. Furthermore, in order to obtain same planar patterns, the first insulating film I1 is processed, thereby forming a select gate insulating film (first gate insulating film) IC, which is formed of the first insulating film I1, in the memory region Rm, and forming a peripheral gate insulating film Ip, which is formed of the first insulating film I1, in the peripheral circuit region Rp.

Through the above-described step, the select gate electrode CG is formed on the main surface of the silicon substrate 1 in the memory region Rm via the select gate insulating film IC. In addition, the peripheral gate electrodes Gp are formed on the main surface of the silicon substrate 1 in the peripheral circuit region Rp via the peripheral gate insulating film Ip.

Next, as illustrated in FIG. 18, a protective film LP1 is formed so as to integrally cover the main surface of the silicon substrate 1 in the memory region Rm, the select gate electrode CG, the main surface of the silicon substrate 1 in the peripheral circuit region Rp, and the peripheral gate electrodes Gp. In this process, as the protective film LP1, for example, an insulating film mainly comprising silicon oxide is formed by about 3 nm by the thermal oxidation method or the CVD method. The effects of forming the protective film LP1 and the effects of using the above-described material as the protective film LP1 in the manufacturing method of the present first embodiment will be explained later in detail.

Subsequently, a first dummy film LD1 is formed so as to cover the protective film LP1. In this process, as the first dummy film LD1, for example, a polycrystalline silicon film containing a p-type (second conduction type) impurity is deposited by about 80 nm by the CVD method. The effects of forming the first dummy film LD1 and the effects of using the above-described material as the first dummy film LD1 in the manufacturing method of the present first embodiment will be explained later in detail.

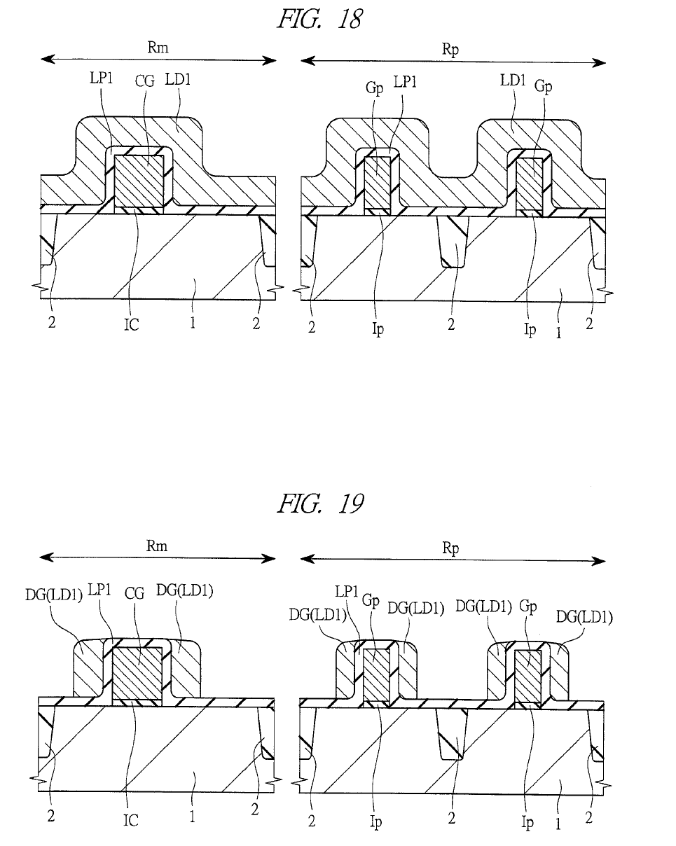

Next, as illustrated in FIG. 19, the first dummy film LD1 is subjected to an etch-back step (see above-described description of FIG. 8), thereby forming dummy gates DG, which is formed of the first dummy film LD1, on the sidewalls of the select gate electrode CG of the memory region Rm and the peripheral gate electrodes Gp of the peripheral circuit region Rp via the protective film LP1.

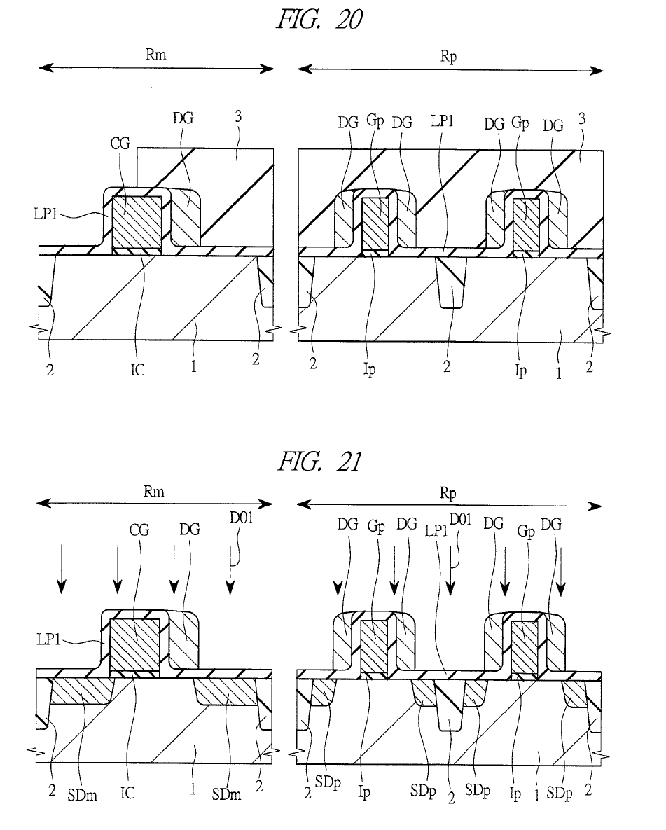

Next, as illustrated in FIG. 20, the dummy gate DG that is on one side of the select gate electrode CG of the memory region Rm is removed. In order to remove the dummy gate DG, first, a photoresist film 3, which is patterned so that at least a sidewall portion of one side of the select gate electrode CG is exposed, is formed by the photolithography method. Then, dry etching is carried out with using the photoresist film 3 as an etching mask, thereby removing the dummy gate DG on one side of the select gate electrode CG of the memory region Rm. Thereafter, the photoresist film 3 is removed.

As described above, through the steps of FIG. 18 to FIG. 20, in the manufacturing method of the present first embodiment, the dummy gate DG is formed to be arranged adjacent to either one of a pair of sidewall surfaces of the select gate electrode CG in the memory region Rm on the silicon substrate 1. Also, in the peripheral circuit region Rp on the silicon substrate 1, the dummy gates DG are formed to be arranged adjacent to both sides of a pair of sidewall surfaces of the peripheral gate electrode Gp. Herein, in the manufacturing method of the first embodiment, since the protective film LP1 is formed in the step of above-described FIG. 18, the dummy gates DG are formed so as to be adjacent to the sidewall surfaces of the gate electrodes CG and Gp, respectively, via the protective film LP1.

Next, as illustrated in FIG. 21, memory source/drain regions (first semiconductor regions) SDm are formed at portions in the main surface of the silicon substrate 1 in the memory region Rm, wherein the portions are below and lateral to the select gate electrode CG and the dummy gate DG (particularly, at the portions below and lateral to the part where both the electrodes are not adjacent to each other). Moreover, peripheral source/drain regions (second semiconductor regions) SDp are formed at portions in the main surface of the silicon substrate 1 in the peripheral circuit region Rp, wherein the portions are below and lateral to the dummy gates DG (particularly, at the portions below and lateral to the parts where the dummy gates are not adjacent to the peripheral gate electrodes Gp).

Regarding the memory region Rm, the main surface of the silicon substrate 1 is subjected to ion implantation D01 with using the select gate electrode CG and the dummy gate DG as an ion implantation mask, thereby forming the memory source/drain regions SDm. At this point, also for the peripheral circuit region Rp, a photoresist film is formed in the region of the p-type MIS transistor, and the main surface of the silicon substrate 1 is subjected to the same ion implantation D01 with using the photoresist film, the peripheral gate electrode Gp, and the dummy gates DG as an ion implantation mask. In this manner, the peripheral source/drain regions SDp of the n-type MIS transistor can be formed. The effects of carrying out the ion implantation D01 as described above in order to form the memory source/drain regions SDm in the manufacturing method of the present first embodiment will be described later in detail.

In the ion implantation D01, for example, arsenic ions of the group V are implanted into the silicon substrate 1 of a group IV with acceleration energy of 5 to 40 keV and with a dose amount of about 1×10¹⁵ to 4×10¹⁵ cm⁻². Therefore, the memory source/drain regions SDm and the peripheral source/drain regions SDp are n-type semiconductor regions.

Further, in the region in which the p-type MIS transistor is to be formed in the peripheral circuit region Rp, p-type peripheral source/drain regions SDp are necessary to be formed. In order to form them, the region in which the n-type MIS transistor is to be formed is covered by a photoresist film or the like formed by the photolithography method, and the above-described ion implantation D01 is carried out with using the photoresist film as an ion implantation mask. Then, a p-type impurity such as boron (B) ions (or BF₂ ions) of the group III are implanted into the region in which the p-type MIS transistor is to be formed.

Moreover, for example, in the ion implantation D01, phosphor (P) ions may be further implanted in addition to arsenic ions.

In the manufacturing method of the present first embodiment, the above-described ion implantation D01 is carried out in the state in which the select gate electrode CG is covered by the protective film LP1. In this manner, in a planar view, a distance (offset) corresponding to the thickness of the protective film LP1 can be caused between the memory source/drain region SDm formed in the portion below and lateral to the select gate electrode CG and the select gate electrode CG. In order to compensate for that, the ion implantation D01 may be angled to be oblique implantation instead of vertical implantation with respect to the substrate. In a thermal treatment for activation and diffusion of the impurities to be carried out after the ion implantation D01, the offset can be eliminated by controlling the diffusion distance by the temperature and time thereof.

Next, the dummy gates DG of the memory region Rm and the peripheral circuit region Rp of the silicon substrate 1 are removed by isotropic dry etching.

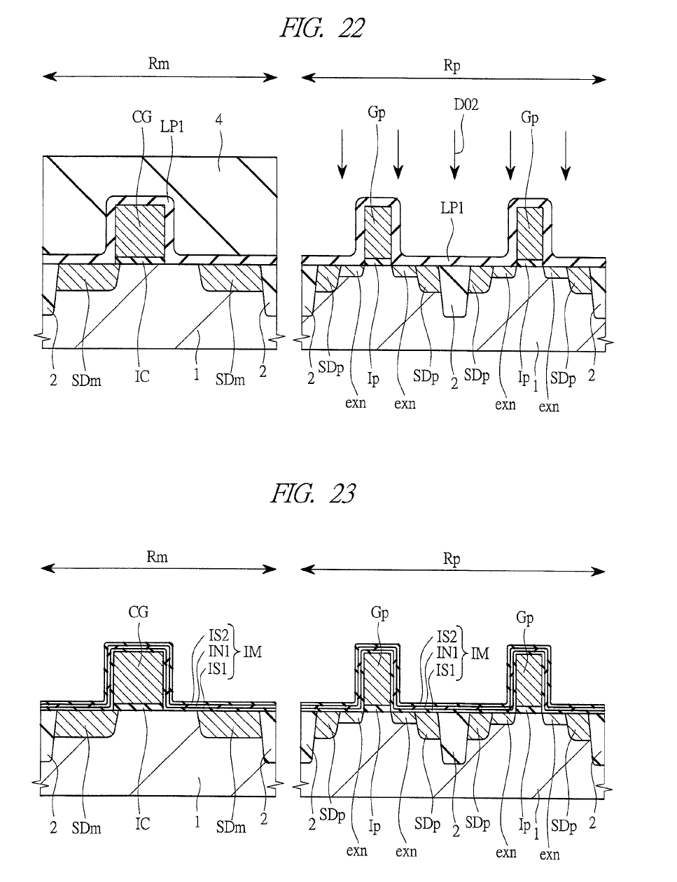

Thereafter, as illustrated in FIG. 22, a photoresist film 4, which is patterned so as to cover the memory region Rm, is formed by the photolithography method. Then, ion implantation D02 is carried out with using the photoresist film 4 as an ion implantation mask. In the ion implantation D02, a photoresist film is formed in the region in which the p-type MIS transistor is to be formed in the peripheral circuit region Rp, and arsenic ions are implanted with using the photoresist film as an ion implantation mask. As a result, in the region of the peripheral circuit region Rp in which the n-type MIS transistor is to be formed, the peripheral gate electrode Gp serves as an ion implantation mask, and extension regions (third semiconductor regions) “exn” which are n-type semiconductor regions are formed at portions in the main surface of the silicon substrate 1 in the peripheral circuit region Rp, wherein the portions are below and lateral to the peripheral gate electrode Gp. Note that, in the ion implantation D02, the arsenic ions are implanted so that the acceleration energy and the dose amount are lower than those of the ion implantation D01 of above-described FIG. 21. Therefore, the extension regions exn are formed so as to have the same conduction type as the peripheral source/drain regions SDp, have a lower impurity concentration than the impurity concentration of the peripheral source/drain regions SDp, and be shallower than the peripheral source/drain regions SDp. Then, the photoresist film 4 is removed. The effects of forming the extension regions exn of the peripheral circuit region Rp in the above-described manner in the manufacturing method of the present first embodiment will be explained later in detail.

When a p-type extension region is to be formed in the region in which the p-type MIS transistor is to be formed in the peripheral circuit region Rp, an ion implantation mask is separately provided by a photoresist film as same as the method of above-described FIG. 21, thereby implanting impurity ions having a different polarity by another step.

In a subsequent step, thermal treatment is carried out in order to activate and diffuse the memory source/drain regions SDm, the peripheral source/drain regions SDp, the extension regions exn, etc. formed by the ion implantation D01 and D02. In the thermal treatment, for example, thermal treatment is carried out at 1000° C. for 10 seconds by RTA (Rapid Thermal Anneal).

In the manufacturing method of the first embodiment, the step in which the above-described ion implantation D02 is carried out in the state in which the peripheral gate electrodes Gp are covered by the protective film LP1 has been described. In this manner, in a planar view, offset corresponding to the thickness of the protective film LP1 is caused between the peripheral source/drain region SDp formed in the portion below and lateral to the peripheral gate electrode Gp and the peripheral gate electrode Gp. In order to compensate for that, the ion implantation D02 may be angled to be oblique implantation instead of vertical implantation with respect to the substrate.

In the above-mentioned RTA step, the offset may be eliminated in the thermal treatment, which is for activation and diffusion of the impurities, by controlling the diffusion distance by the temperature and time thereof.

Also, the offset between the peripheral gate electrodes Gp and the peripheral source/drain regions SDp can be eliminated by removing the protective film LP1 of the peripheral circuit region Rp before carrying out the ion implantation D02, and carrying out the ion implantation D02 after that.

Next, as illustrated in FIG. 23, wet etching by a hydrogen fluoride (hydrofluoric acid, HF) solution is carried out, thereby removing the protective film LP1 of the memory region Rm and the peripheral circuit region Rp. Then, a charge accumulating film IM is formed so as to integrally cover the main surface of the silicon substrate 1 in the memory region Rm and the select gate electrode CG. As is described in the step of above-described FIG. 7, the charge accumulating film IM (the charge accumulating film IMa in above-described FIG. 7) is formed of a stacked insulating film of three layers. Various proposals have been made about the optimal film thickness and material about the constitution of the charge accumulating film IM; however, in the manufacturing method of the first embodiment, the charge accumulating film is formed so as to have the following constitution. That is, a first silicon oxide film IS1 having a thickness of about 4nm, a first silicon nitride film IN1 having a thickness of about 5 nm, and a second silicon oxide film IS2 having a thickness of about 5 nm are sequentially formed from the side close to the silicon substrate 1.

In this manner, in the manufacturing method of the first embodiment, at least, after the memory source/drain regions SDm are formed in the step of above-described FIG. 21, the charge accumulating film IM of the step of FIG. 23. The effects of carrying out the above-described steps in this order will be explained later in detail.

ISSG (In Situ Steam Generation) method is known as a formation method of the stacked films composing the above-described charge accumulating film IM. Each of the first silicon oxide film IS1, the first silicon nitride film IN1 on the first silicon oxide film IS1, and the second silicon oxide film IS2 on the first silicon nitride film IN1 on the silicon substrate 1 formed of single-crystal or polycrystal silicon can be formed by the ISSG method. Particularly, regarding the second silicon oxide film IS2 on the first silicon nitride film IN1, a silicon nitride film is deposited in advance by about 8 to 9 nm, and oxidation by the ISSG method is carried out so that the film has a thickness of about 5 nm that is equivalent to the same formed on silicon. As a result, the silicon nitride film is consumed by about 4 nm, and so the stacked structure having the above-described film thickness can be formed.

Note that, in the present step, unless a special mask process is carried out, a similar charge accumulating film IM is also formed in the peripheral circuit region Rp, which is not problematic in the manufacturing method of the first embodiment.

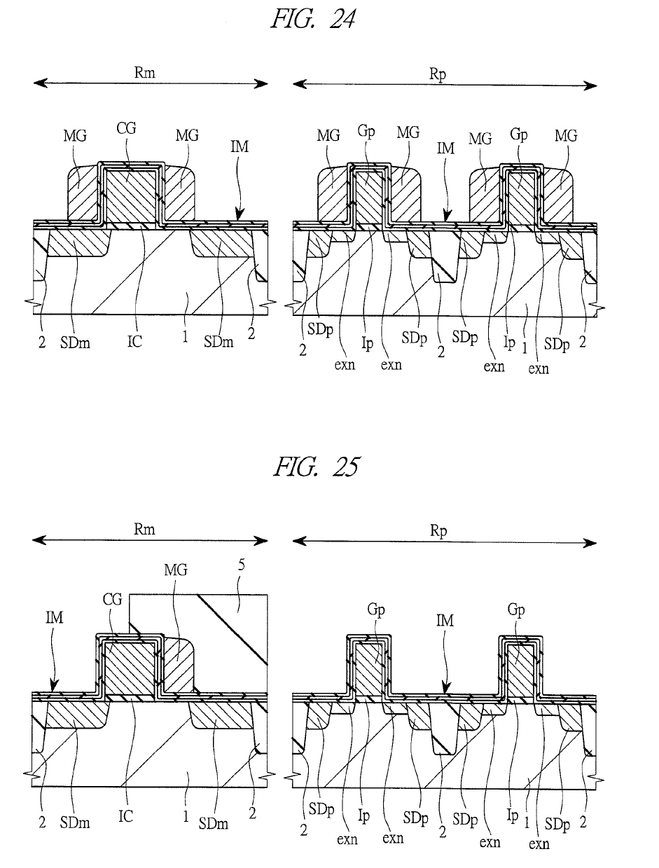

Next, as shown in FIG. 24, memory gate (second gate electrodes) electrodes MG, which are, for example, a conductor film mainly formed of polycrystalline silicon containing a p-type (second conduction type) impurity, are formed so that the memory gate electrodes MG are arranged to be adjacent to the sidewall surfaces of the select gate electrode CG of the memory region Rm of the silicon substrate 1. In order to form them, a polycrystalline silicon film containing a p-type impurity is deposited by about 80 nm by, for example, the CVD method and subjected to an etch-back step, thereby forming the memory gate electrodes MG having the above-described shape. Note that, in this step, unless a special mask process is carried out, similar memory gate electrodes MG are formed on the sidewalls of the peripheral gate electrodes Gp of the peripheral circuit region Rp of the silicon substrate 1, which is not problematic in the manufacturing method of the first embodiment.

Next, as shown in FIG. 25, the memory gate electrode MG on one side of the select gate electrode CG of the memory region Rm of the silicon substrate 1 is removed. Particularly, in the manufacturing method of the first embodiment, the memory gate electrode MG on the side that is opposite to the side where the dummy gate DG remained is removed by the step of above-described FIG. 20 so as to remain the memory gate electrode MG on the sidewall on the side that is same as the side where the dummy gate DG remained.

In order to remove the electrode, first, a photoresist film 5 which is patterned so that at least one of the sidewall portions of the select gate electrode CG is exposed is formed by the photolithography method. Particularly, in the memory region Rm, the photoresist film 5 having a similar pattern as the photoresist film 3 formed in the step of above-described FIG. 20 is formed. Then, dry etching is carried out with using the photoresist film 5 as an etching mask, thereby removing the memory gate electrode MG on one side of the select gate electrode CG of the memory region Rm. Then, the photoresist film 5 is removed.

Note that, if the photoresist film 5 is patterned so as to also expose the peripheral circuit region Rp, the above-described dry etching acts also on the memory gate electrodes MG of the peripheral circuit region Rp, and the memory gate electrodes are removed.

Hereinabove, through the steps of FIG. 24 and FIG. 25, in the manufacturing method of the first embodiment, the memory gate electrode MG is formed so that the memory gate electrode is arranged to be adjacent to the sidewall surface which is the same sidewall surface on which the dummy gate is formed in the step of above-described FIG. 20 among the pair of the sidewall surfaces of the select gate electrode CG. Furthermore, the memory gate electrode MG is formed so as to be arranged at an above and lateral to the memory source/drain region SDm, which is formed in the step of above-described FIG. 21, on the main surface of the silicon substrate 1 via the charge accumulating film IM.

At this point, the first dummy film LD1 (which later serves as the dummy gates DG) described in the step of above-described FIG. 18 and the polycrystalline silicon film which serves as the memory gate electrode MG described in the step of above-described FIG. 24 are formed to have a film thicknesses (about 80 nm) which are about the same. In addition, both of them are processed by etch back so that the dummy gate DG and the memory gate electrode MG have the shape to be arranged adjacent to the sidewall of the select gate electrode CG. Therefore, in the manufacturing method of the present first embodiment, the channel-length-direction sizes of the dummy gate DG and the memory gate electrode MG are almost the same. As a result, according to the manufacturing method of the first embodiment, the memory source/drain region SDm formed at the portion below and lateral to the dummy gate DG has the structure that is disposed at a portion below and lateral to the memory gate electrode MG, even when it is viewed from the memory gate electrode MG which is formed later after removing the dummy gate DG.

As a result, a constitution that is similar to the non-volatile memory NVMa which has been studied by the present inventors and described above can be also formed by the first embodiment.

In subsequent steps, as same as the steps described with reference to above-described FIG. 10, FIG. 11, etc., sidewall spacers “sp” formed of a silicon oxide film and a metal silicide layer “sc” formed of cobalt silicide, nickel silicide, or the like are formed.

Through the above steps, on the same silicon substrate 1, the non-volatile memory NVM of the first embodiment can be formed in the memory region Rm, and the n-type MIS transistor Q1, which is an example of a peripheral circuit element, can be formed in the peripheral circuit region Rp.

Hereinafter, the functions and effects provided by the manufacturing method of the semiconductor device of the present first embodiment and the semiconductor device of the present first embodiment formed by the manufacturing method will be explained in detail.

As a feature of the manufacturing method of the present first embodiment, there is the step in which the charge accumulating film IM is formed in the step of above-described FIG. 22, after the memory source/drain regions SDm are formed by the ion implantation D01 in the step of above-described FIG. 21. This step can be carried out since the dummy gates DG serve as an ion implantation mask that is required when the ion implantation D01 is carried out. More specifically, the memory gate electrode MG, which can be formed only after the charge accumulating film IM is formed, is not used as the ion implantation mask, and the dummy gates DG, which can be formed independently from the formation step of the charge accumulating film IM, are used as the ion implantation mask.

In this manner, according to the manufacturing method of the semiconductor device of the first embodiment, the ion implantation D01 for forming the memory source/drain regions SDm can be carried out before forming the charge accumulating film IM. The following effects are attained by this. That is, the memory source/drain regions SDm can be formed without damaging the charge accumulating film IM due to the ion implantation D01. In this manner, the non-volatile memory NVM having a good charge retention characteristic and higher reliability of memory operation can be formed by the manufacturing method of the first embodiment in which no ion implantation step is carried out for the silicon substrate 1 in the steps after the charge accumulating film IM is formed. As a result, the characteristics of the semiconductor device having the non-volatile memory can be improved.

The material of the dummy gate DG may be a conductor film or an insulating film, and the type of the material is not limited from the viewpoint that the dummy gates DG are used in place of the memory gate electrode MG as the ion implantation mask of the ion implantation D01. Regarding this point, in the manufacturing method of the present first embodiment, the process has been described on the assumption that the conductor film mainly formed of polycrystalline silicon containing the p-type impurity is formed as the dummy gates DG. This is for the reason that the material has been selected based on the viewpoint that the dummy gates DG formed in the steps of above-described FIG. 18 to FIG. 20 are more preferably formed by the same material as the memory gate electrode MG, which is formed in the later steps of above-described FIG. 24 and FIG. 25. As is described in the steps of above-described FIG. 24 and FIG. 25, the memory gate electrode MG is a conductor film mainly formed of polycrystalline silicon containing the p-type impurity. The reason that it is more preferred to form the dummy gates DG by the same material as the memory gate electrode MG will be explained below in detail.

According to the manufacturing method of the first embodiment, the memory source/drain regions SDm to be arranged at the portions below and lateral to the memory gate electrode MG are formed by the ion implantation D01 using the dummy gates DG as the ion implantation mask. In this process, from the viewpoint that it is desirable to form elements as designed, after the dummy gate DG is removed, it is preferred to arrange the memory gate electrode MG at the same position and by the same shape as the dummy gate DG. Therefore, as described above, the material that is the same as that of the memory gate electrode MG is used as the material of the dummy gates DG. As a result, when both of them are formed by the same conditions and processed by the same conditions, the dummy gate DG and the memory gate electrode MG can be readily formed at the same position and by the same shape. When the dummy gates DG are formed by the same material as the memory gate electrode MG in this manner, deviation from the designed size that can be posed in the process of forming the non-volatile memory NVM can be reduced. Consequently, processing accuracy can be further improved in the manufacturing method of the first embodiment in which the dummy gates DG, which are effective as described above, are used. As a result, the characteristics of the semiconductor device having the non-volatile memory can be further improved.

In addition, if merely consider use of the dummy gates DG as the ion implantation mask of the ion implantation D01, the protective film LP1 is not required to be formed below the dummy gates DG in the above-described step of FIG. 18. On the other hand, in the manufacturing method of the first embodiment, it is more preferred to form the protective film LP1 before forming the dummy gates DG. The reason therefor is as follows.

As described above, the dummy gates DG are subjected to anisotropic etching for processing the shapes thereof and subjected to etching for removal in a later step. In these processes, the protective film LP1 can be used as an etching stopper film in order to protect the select gate electrode CG, which is a constituent element of the non-volatile memory NVM, the silicon substrate 1, etc. from damage of the etching. Consequently, the damage generated by etching in the manufacturing method of the first embodiment which is effective as described above and in which the dummy gates DG are used can be further reduced. As a result, the characteristics of the semiconductor device having the non-volatile memory can be further improved.

From this point of view, the larger the difference between the etching rate of the protective film LP1 and the etching rate of the dummy gates DG with respect to predetermined etching, the more preferable. More specifically, the combination of the protective film LP1 and the dummy gates DG is not limited to the silicon oxide film and the polycrystalline silicon film, and a combination of the materials capable of further increasing the selectivity upon the etching is preferable. As described above, if the polycrystalline silicon film is used as the dummy gates DG according to the condition that the same material as the memory gate electrode MG is used, for example, a silicon oxide film or a silicon nitride film has an etching rate that is different from that of the polycrystalline silicon film and can be selected as the material of the protective film LP1. In the first embodiment, the example in which the insulating film mainly formed of silicon oxide is used as the protective film LP1 has been described.

In addition, the material of the memory gate electrode MG is required to function as a gate electrode of a so-called MIS transistor and is not limited to the polycrystalline silicon film containing a p-type impurity. More specifically, the material of the memory gate electrode MG may be, for example, a polycrystalline silicon film containing an n-type impurity or a metal material.

For example, when a polycrystalline silicon film containing an n-type impurity is used for the memory gate electrode MG, the initial threshold voltage of the memory gate transistor part can be lowered compared with the case in which a polycrystalline silicon film containing a p-type impurity is used for the memory gate electrode MG. Moreover, the amount of the holes to be injected into the charge accumulating film IM upon erase operation can be reduced by the amount corresponding to the initial threshold voltage, and erase operation to a desired erase threshold voltage can be carried out with a smaller hole injection amount. As a result, the damage caused on the charge accumulating film IM by the BTBT hot hole injection can be reduced. In this manner, the smaller the initial threshold voltage and the hole injection amount is, the weaker the electric field applied to barrier insulating films (first and second silicon oxide films IS1 and IS2) when holes are injected until a desired erase threshold voltage is achieved. As a result, the hole retention property upon erase operation is improved.

On the other hand, when a polycrystalline silicon film containing a p-type impurity is used for the memory gate electrode MG, since the initial threshold voltage is high, electrons can be injected up to a desired write threshold voltage while reducing the injection amount of the electrons upon write operation. As a result, the damage caused on the charge accumulating film IM by hot electron injection can be reduced. The higher the initial threshold voltage is and smaller the electron injection amount is in this manner, the weaker the electric field used for barrier insulating films (first and second silicon oxide films IS1 and IS2) when electrons are injected until the desired write threshold voltage is achieved. As a result, the electron retention property upon write operation is improved.

Further, when a polycrystalline silicon film containing a p-type impurity is used for the memory gate electrode MG, the erase operation can be realized by applying a voltage between the memory gate electrode MG and the silicon substrate 1 and injecting the holes in the memory gate electrode MG into the charge accumulating film IM by the tunneling phenomenon. In such an erase method, although the speed thereof is slower than the erase operation that utilizes the hot holes by the BTBT phenomenon, the damage onto the charge accumulating film IM can be reduced. As a result, the retention property of the memory can be improved.

On the other hand, in the non-volatile memory NVMa and the manufacturing method thereof which have been studied by the present inventors and described with reference to above-described FIG. 7 to FIG. 11, the memory gate electrode MGa that has the conduction type opposite to that of the memory source/drain region SDma cannot be easily formed. That is because, after the memory gate electrode MGa is formed, the ion implantation Da for forming the memory source/drain region SDma is carried out while using the memory gate electrode MGa as an ion implantation mask. As a result, the memory gate electrode MGa contains a dopant at a concentration that is at the same level as the dopant implanted into the memory source/drain region SDma. Even if a large amount of impurity that achieves the opposite conduction type is contained in the memory gate MGa electrode when the memory gate electrode MGa is formed, the ion implantation Da acts in the direction to cancel them out. Note that, in this state, the majority carrier in the memory gate electrode MGa is cancelled out, and the memory gate electrode MGa contains the impurity having the polarity that is same to the impurity implanted into the memory source/drain region SDma, wherein the concentrations thereof are at the same level.

On the other hand, according to the manufacturing method of the first embodiment, the ion implantation D01 for forming the memory source/drain regions SDm is carried out before forming the memory gate electrode MG. Therefore, the impurity ions implanted into the memory source/drain regions SDm by the ion implantation D01 are not implanted into the memory gate electrode MG. Thus, the conduction type of the memory gate electrode MG can be suitably selected. Particularly, the conduction types of the non-volatile memory NVM in which the memory source/drain regions SDm and the memory gate electrode MG are mutually opposite conduction types like the above description can be realized. In other words, a semiconductor device having the non-volatile memory NVM having the characteristic that the concentration of the n-type impurity (first impurity) contained in the memory gate electrode MG is lower than the concentration of the n-type impurity in the memory source/drain regions SDm can be realized. As a result, for the above-described reasons, the characteristics of the semiconductor device having the non-volatile memory can be improved. Note that, regarding the conduction types of the memory gate electrode MG and the memory source/drain regions SDm, similar effects can be obtained even when the n-type conduction type and the p-type conduction type are switched with each other.

In addition, forming the memory gate electrode MG after the ion implantation D01, which is for forming the memory source/drain regions SDm, like the manufacturing method of the present first embodiment exerts the following effects. That is, even when the conduction types of the memory gate electrode MG and the memory source/drain regions SD are mutually opposite conduction types, the concentration gradient and a partial PN junction, which are caused when the impurity of the opposite conduction type is implanted into the memory gate electrode MG, cannot be easily formed. The concentration gradient and formation of the PN junction in the memory gate electrode MG cause, for example, ununiformity of characteristics and reduction of the operation speed. Therefore, according to the manufacturing method of the first embodiment, the characteristics of the non-volatile memory NVM can be further improved. As a result, the characteristics of the semiconductor device having the non-volatile memory can be further improved.

As described above, in the manufacturing method of the first embodiment, the process per se of forming the non-volatile memory NVM is effective as an independent formation process. Furthermore, the formation process of the non-volatile memory NVM having the above-described effects is more preferred to be shared with part of the process of forming the MIS transistor Q1 as a peripheral circuit element. This is for the reason that the manufacturing method of the semiconductor device can be simplified when the formation process of the non-volatile memory NVM is shared by the formation process of the peripheral circuit element.

More specifically, the process can be shared in the following manner. In the above-described step of FIG. 12, the first insulating film I1 and the first conductor film E1 can be formed by the same step on the main surface of the silicon substrate 1 in the memory region Rm and the peripheral circuit region Rp. Also, in the above-described step of FIG. 17, the select gate insulating film IC, the select gate electrode CG, the peripheral gate insulating film Ip, and the peripheral gate electrodes Gp can be formed by processing the first insulating film I1 and the first conductor film E1, which are formed in the memory region Rm and the peripheral circuit region Rp of the silicon substrate 1, by the same step. Further, in the above-described steps of FIG. 18 to FIG. 20, the dummy gates DG can be formed by the same steps in the memory region Rm and the peripheral circuit region Rp of the silicon substrate 1. Still further, in the above-described step of FIG. 21, the memory source/drain regions SDm and the peripheral source/drain regions SDp can be formed by subjecting the main surface of the silicon substrate 1 in the memory region Rm and the peripheral circuit region Rp to the same ion implantation D01. Moreover, in the above-described step of FIG. 21, the dummy gates DG formed on the silicon substrate 1 in the memory region Rm and the peripheral circuit region Rp can be removed by the same etching step.

In addition, when a semiconductor device having the non-volatile memory NVM is manufactured in the manner of the manufacturing method of the first embodiment, the MIS transistors Q1 having the extension regions exn can be formed in the peripheral circuit region Rp in the manner of the above-described step of FIG. 22. Generally, in MIS transistors which are miniaturized for the request to enhance performance of a semiconductor device, formation of an LDD structure having the extension regions is required. According to the manufacturing method of the first embodiment, even when the manufacturing method of the non-volatile memory NVM having the above-described effects is used, the MIS transistors Q1 having the extension regions exn can be formed in the peripheral circuit region Rp. As a result, the characteristics of the semiconductor device having the non-volatile memory can be further improved.

Note that, in the case of forming the extension regions exn through the above-described steps described with FIG. 21 and FIG. 22 in the manner of the manufacturing method of the first embodiment, the peripheral source/drain regions SDp are formed before forming the extension regions exn. Therefore, the MIS transistors Q1 formed in the peripheral circuit region Rp of the silicon substrate 1 may have the structure in which offset or overlapping is caused in a planar view between the sidewall spacer sp and the peripheral source/drain region SDp.

Moreover, in the manufacturing method of the first embodiment, for example, the dummy gate DG may be formed to have a smaller planar size than the planar size of the memory gate electrode MG. More specifically, in the above-described step of FIG. 18, the thickness of the first dummy film LD1 is formed to be thinner than the thickness of the polycrystalline silicon film which serves as the memory gate electrode MG formed in the above-described later step of FIG. 24. As a result, when the sidewall-like dummy gate DG after carrying out etch back and the memory gate electrode MG are compared with each other, the former one is formed to have a smaller planar size.

When the size of the dummy gate DG is formed to be smaller than that of the memory gate electrode MG as described above, the structure in which the memory source/drain region SDm and the memory gate electrode MG are more largely overlapped with each other can be obtained. This is for the reason that the memory source/drain region SDm is formed by the ion implantation D01 using the dummy gate DG as the ion implantation mask, and, if the dummy gate DG is smaller, the memory source/drain region SDm can be formed in a wider area.

For example, when thermal oxidation is carried out in the above-described step of FIG. 26 in order to form the sidewall spacers sp, at an end portion of the memory gate electrode MG, a bird's beak can be formed between the memory gate electrode MG and the silicon substrate 1. When such a bird's beak is formed, the voltage applied to the memory gate electrode MG is unnecessarily lowered at the bird's beak, and the electric field effect is not easily generated in the channel. As a countermeasure therefor, in the manufacturing method of the first embodiment, the overlapping of the memory gate electrode MG and the memory source/drain region SDm is further expanded in the above-described manner, so that the influence of the bird's beak can be reduced. Thereby, the electric field effect caused by the voltage applied to the memory gate electrode MG can be more effectively exerted on a channel region, and the operation characteristics of the memory can be improved. As a result, the characteristics of the semiconductor device having the non-volatile memory can be improved.

### Second Embodiment

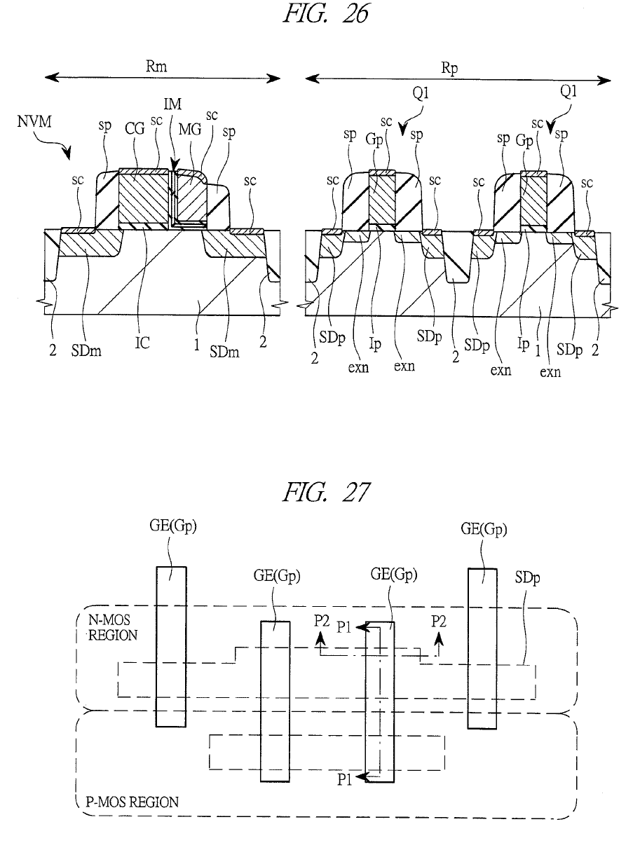

The MIS transistors Q1 serving as peripheral circuit elements formed on the peripheral circuit region Rp in the above-described first embodiment can be used as, for example, MIS transistors Q1 composing an SRAM (Static Random Access Memory) circuit illustrated in FIG. 27. The SRAM circuit uses n-type MIS transistors Qn and p-type MIS transistors Qp and is formed by using a so-called CMOS structure in the gate electrodes GE (peripheral gate electrodes Gp) of both of the n-type MIS transistor Qn and p-type MIS transistor Qp are electrically connected. Herein, the SRAM circuit is one of the elements that require miniaturization most strictly because the SRAM circuit requires six MIS transistors Q1 per a unit memory cell. Therefore, in the above-described CMOS constitution, a structure is desired such that the gate electrodes GE of two types of MIS transistors Qn and Qp are connected by sharing one gate electrode GE instead of electrically connecting them via a wiring layer.

A second embodiment describes a semiconductor device having a non-volatile memory NvM in a memory region Rm on a silicon substrate 1 and has peripheral circuit elements composed of MIS transistors Q1 sharing a gate electrode GE in a peripheral circuit region Rp, and a manufacturing method of the same. Note that, in the manufacturing method of the second embodiment, which will be described below, and the structure of the semiconductor device formed by the manufacturing method that is similar to that described in the above-described first embodiment and the structure similar to the semiconductor device formed by the manufacturing method of the first embodiment have the effects similar to the first embodiment, and repetitive descriptions will be omitted herein unless otherwise stated.

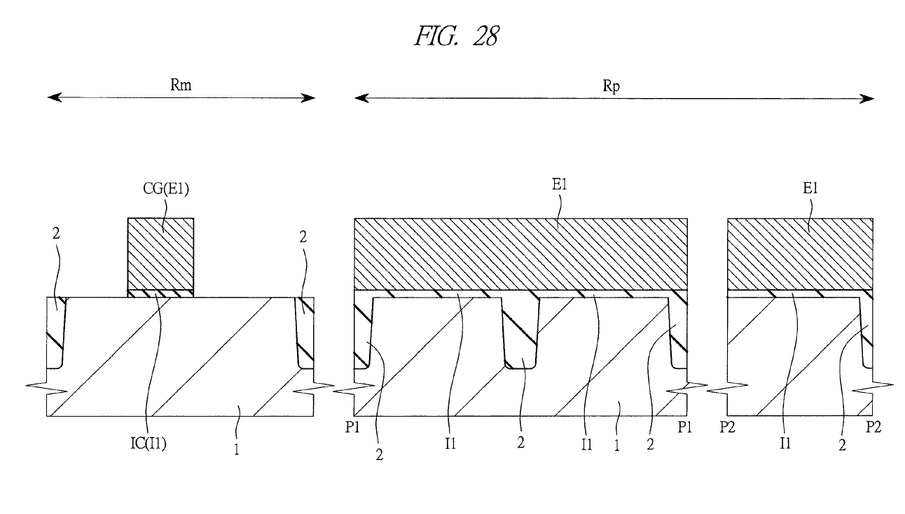

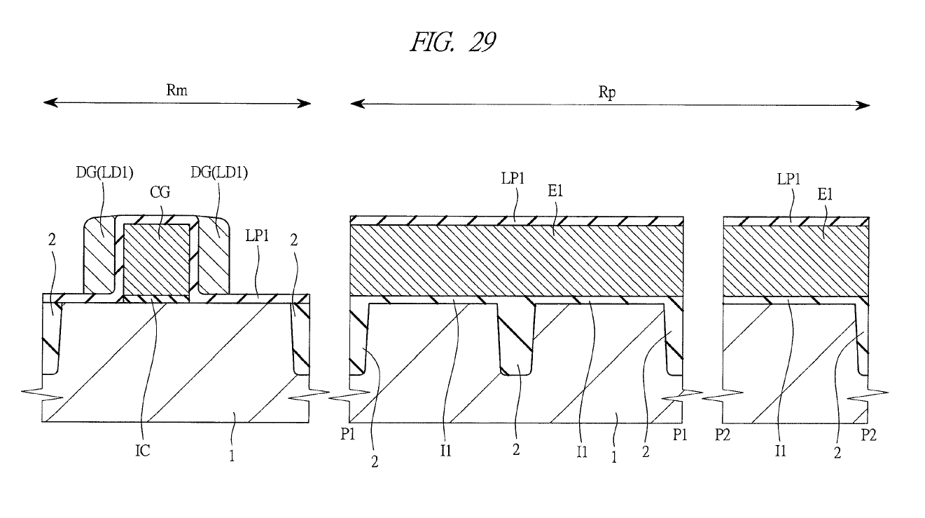

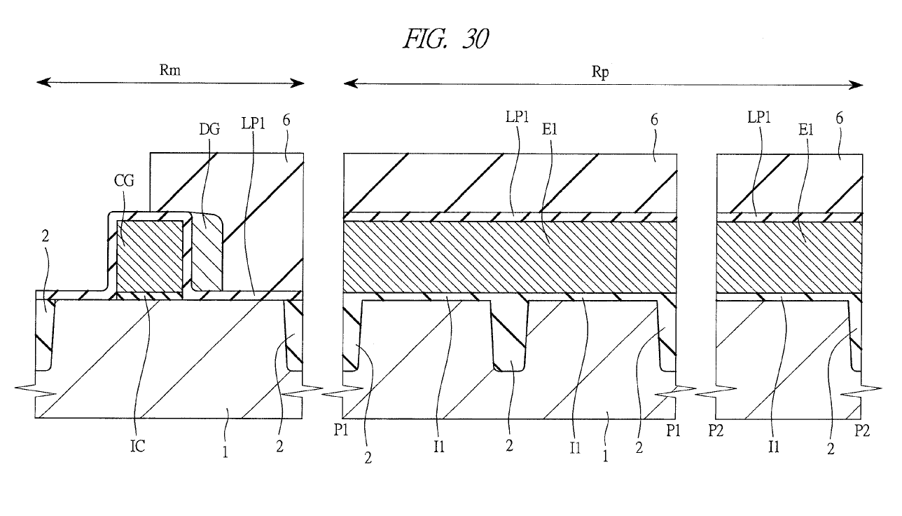

Hereinafter, FIG. 28 to FIG. 36 which will be referred to for description are cross-sectional views during steps of forming the non-volatile memory NVM in the memory region Rm and cross-sectional views during steps of forming the MIS transistors Q1 composing the SRAM circuit in the peripheral circuit region Rp. In the drawings, particularly, the cross-sectional views of main parts of the memory region Rm are illustrated on the left side, the cross-sectional views viewed in the direction of arrows along the line P1-P1 in the above-described SRAM circuit of FIG. 27 are illustrated on the center for the peripheral circuit region Rp, and the cross-sectional views viewed in the direction of arrows along the line P2-P2 are illustrated on the right side. The cross-sectional views taken along the line P1-P1 illustrate the boundary portion between an N-MOS region and a P-MOS region in the peripheral gate electrodes Gp shared by the n-type MIS transistor Qn and the p-type MIS transistor Qp. The cross-sectional views taken along the line P2-P2 are the cross-sectional views along a channel of the MIS transistor Q1 formed in the peripheral circuit region Rp.

In the manufacturing method of the present second embodiment, first, a step that is similar to the step described above in FIG. 12 in the above-described first embodiment is carried out. More specifically, isolation portions 2 are formed in the main surface of the silicon substrate 1, thereby defining the region in which the n-type MIS transistor or the p-type MIS transistor is to be formed in the peripheral region Rp. Subsequently, a first insulating film I1 formed of a silicon oxide film and a first conductor film E1 formed of a polycrystalline silicon film are formed. Herein, the memory region Rm and the peripheral circuit region Rp are subjected to a similar step.

In this process, after the first conductor film E1 formed of the undoped polycrystalline silicon film is formed, a photoresist film which is patterned so as to cover the peripheral circuit region Rp is formed, and an n-type impurity is ion-implanted into the first conductor film E1 of the memory region Rm with using the photoresist film as an ion implantation mask. Then, for example, thermal treatment at 950° C. is carried out for about 120 seconds, thereby activating the n-type impurity implanted into the first conductor film E1 of the memory region Rm.

Thereafter, as illustrated in FIG. 28, only the first insulating film I1 and the first conductor film E1 of the memory region Rm are processed as well as the above-described step of FIG. 17, thereby forming a select gate electrode CG and a select gate insulating film IC. In this process, the peripheral circuit region Rp is not subjected to processing.

Next, as illustrated in FIG. 29, a protective film LP1 and a first dummy film LD1 are formed as same as the above-described step of FIG. 18. Then, as same as the above-described step of FIG. 19, the first dummy film LD1 is subjected to etch back, thereby depositing dummy gates DG. Herein, in the manufacturing method of the second embodiment, since the first conductor film E1 of the peripheral circuit region Rp is not processed in the previous step, the first dummy film LD1 is uniformly deposited on the first conductor film E1 of the peripheral circuit region Rp in this step. Then, the uniform first dummy film LD1 is subjected to etch back in this manner in the peripheral circuit region Rp. Therefore, the first dummy film LD1 can be entirely removed in the peripheral circuit region Rp.

Next, as shown in FIG. 30, as well as the above-described step of FIG. 20, etching using a photoresist film 6 (similar to the above-described photoresist film 3 of FIG. 20) as an etching mask is carried out, thereby removing one of the dummy gates DG on both sides of the select gate electrode CG.

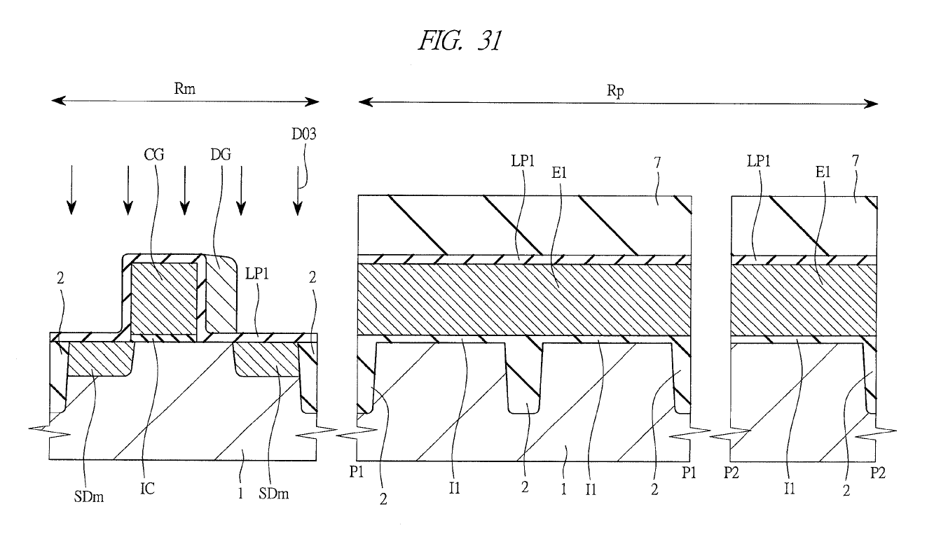

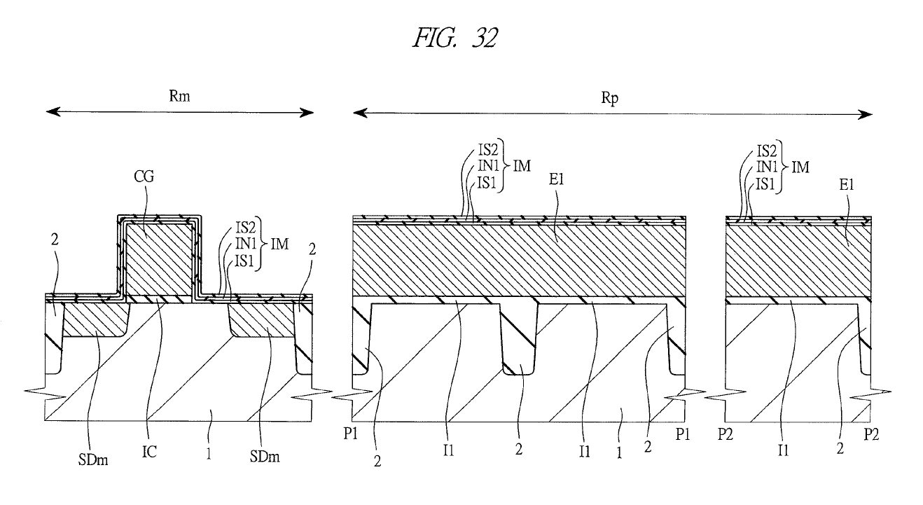

Next, as illustrated in FIG. 31, a photoresist film 7 which has an opening in the memory region Rm on the silicon substrate 1 and covers the peripheral circuit region Rp is formed by the photolithography method or the like. Then, ion implantation D03 similar to the above-described ion implantation D01 of FIG. 21 is carried out with using the photoresist film 7 and the select gate electrode CG as an ion implantation mask, thereby forming memory source/drain regions SDm as same as FIG. 21 in the memory region Rm. Herein, since the peripheral circuit region Rp is covered by the photoresist film 7, no semiconductor region is formed therein even when the ion implantation D03 is carried out. After the ion implantation D03, the photoresist film 7 is removed, and the dummy gate DG and the protective film LP1 are removed as same as above-described FIG. 21.

Herein, the protective film LP1 is formed on the sidewall surface of the select gate electrode CG which is not adjacent to the dummy gate DG among the sidewalls of the select gate electrode CG which functions as the ion implantation mask. Therefore, offset is caused by the amount corresponding to the thickness of the protective film LP1 in a planar view between the select gate electrode CG and the memory source/drain region SDm. In order to compensate for that, the ion implantation D03 may be angled to be oblique implantation instead of vertical implantation with respect to the silicon substrate 1. Also, the offset can be eliminated by controlling the diffusion distance by the temperature and the time of later RTA.

Next, as illustrated in FIG. 32, as same as the above-described step of FIG. 23, a charge accumulating film IM formed of a first silicon oxide film IS1, a first silicon nitride film IN1, and a second silicon oxide film IS1 is formed. In this process, in the memory region Rm, the charge accumulating film IM is formed so as to cover the main surface of the silicon substrate 1 and the select gate electrode CG (as same as above-described FIG. 23). On the other hand, in the peripheral circuit region Rp, the first conductor film E1 is uniformly formed, and the charge accumulating film IM is formed so as to cover the first conductor film E1.

Herein, in the manufacturing method of the second embodiment, during the step of forming the charge accumulating film IM, the following thermal treatment is carried out. After the first silicon oxide film IS1 is formed, thermal treatment (annealing) is carried out at about 950° C. to 1050° C. in a gas atmosphere containing oxygen and nitrogen such as a nitrogen monoxide (NO) atmosphere or a dinitrogen monoxide (N₂O) atmosphere for about 30 seconds to 10 minutes. Then, the first silicon nitride film IN1 and the second silicon oxide film IS2 are formed. As a result, a good state of the interface between the silicon substrate 1 and the first silicon oxide film IS1 can be achieved, and the resistance to hot carriers, etc. can be improved.

The charge accumulating film IM having the function of retaining charges can be formed by forming and stacking the three types of insulating films in the manner of above-described step of FIG. 23. However, it is more preferable to include the step of carrying out thermal treatment as described above with respect to the first silicon oxide film IS1 like the manufacturing method of the second embodiment. This is for the reason that, as described above, the good state of the interface between the silicon substrate 1 and the first silicon oxide film IS1 can be achieved and that the hot carrier resistance can be improved. As a result, the characteristics of the semiconductor device having the non-volatile memory can be improved.

The reason that the thermal treatment that is effective as described above can be carried out in the manufacturing method of the non-volatile memory NVM using the dummy gate DG like the second embodiment is that the characteristics of the manufacturing step included in the second embodiment attains effects. This matter will be explained later in detail with a later step.

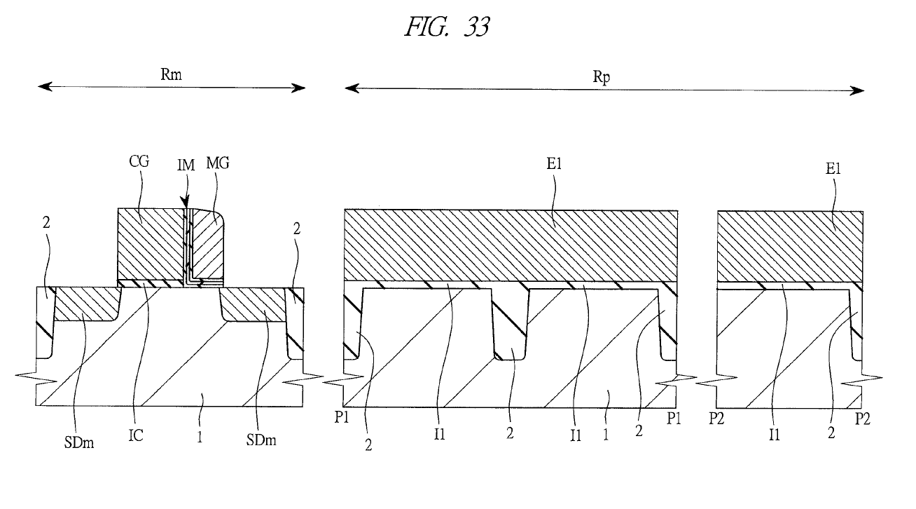

Next, as illustrated in FIG. 33, the memory gate electrode MG are formed as same as the steps of above-described FIG. 24 and FIG. 25.

In a subsequent step, peripheral circuit elements of the peripheral circuit region Rp will be formed. The manufacturing method of the present second embodiment describes a semiconductor device having the SRAM circuit composed of CMOS, wherein the n-type MIS transistor Qn and the p-type MIS transistor Qp serving as the peripheral circuit elements share a gate electrode like above-described FIG. 27. Particularly, it is known that a CMOS constitution achieving a high speed and high performance can be achieved when the gate electrode of the n-type MIS transistor Qn is formed of polycrystalline silicon containing an n-type impurity, and the gate electrode of the p-type MIS transistor Qp is formed of polycrystalline silicon containing a p-type impurity.

Therefore, the above-described SRAM circuit of FIG. 27 which is a peripheral circuit element of the semiconductor device of the second embodiment also has a structure in which the peripheral gate electrodes Gp of the N-MOS region contain an n-type impurity, and the peripheral gate electrodes Gp of the P-MOS region contain a p-type impurity. In order to achieve this structure, for example, gate electrodes having different polarities may be separately fabricated by the photolithography method or an etching process, and one gate electrode that connects both of the gate electrodes may be formed. Meanwhile, since the SRAM circuit part is one of the regions that require the strictest miniaturization as described above, rather than carrying out the above-described processing of separate fabrication, it is more preferable to form one gate electrode having portions of both polarities by separate implantations of impurity ions. This is for the reason that, when the separate implantations of the impurity ions by ion implantation are employed, a finer pattern can be readily formed by just forming a photoresist film by the photolithography method as an ion implantation mask without actual shape processing.

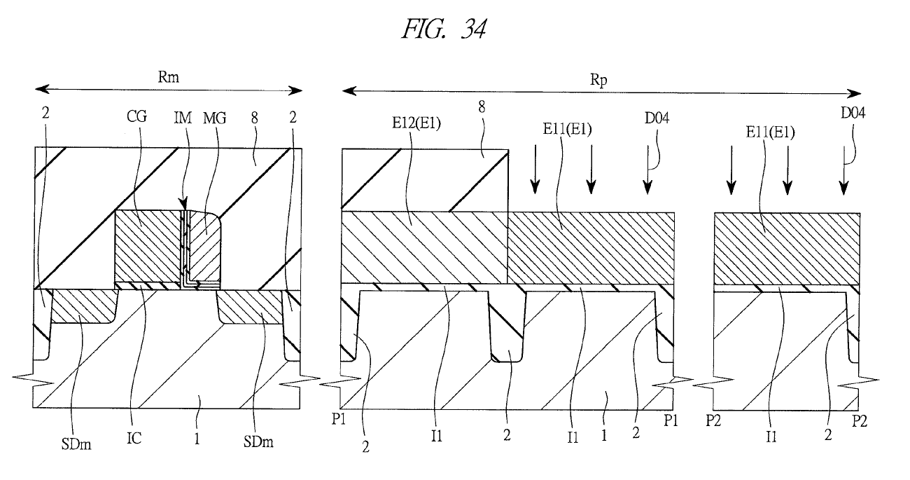

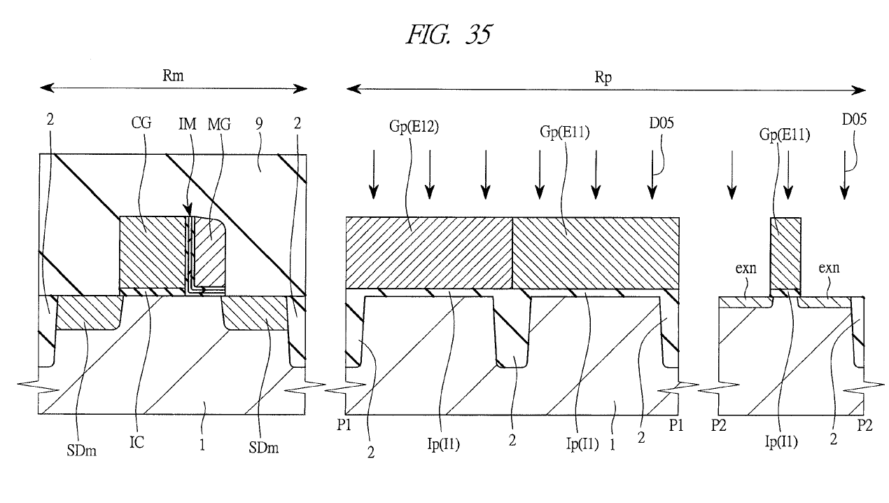

As illustrated in FIG. 34, in the peripheral circuit region Rp, an impurity (donor) to obtain the n-type (first conduction type) is implanted into a first portion E11 which will later serve as the peripheral gate electrode Gp of the n-type MIS transistor (above-described n-type MIS transistor Qn of FIG. 27) in the first conductor film E1. In order to carry out this implantation, first, a second portion E12 which will later serve as the p-type MIS transistor (above-described p-type MIS transistor Qp of FIG. 27) in the peripheral gate electrode Gp of the peripheral circuit region Rp of the silicon substrate 1 is covered by a photoresist film 8. The photoresist film 8 is formed so as to also cover the memory region Rm of the silicon substrate 1. Subsequently, while using the photoresist film 8 as an ion implantation mask, ion implantation D04 which implants ions of, for example, arsenic or phosphor is carried out. As a result, the first portion E11 of the first conductor film E1 becomes to contain the n-type impurity.

Subsequently, another photoresist film is formed so as to cover the first portion E11 of the first conductor film E1, and an impurity (acceptor) which obtains the p-type (second conduction type) such as boron is implanted into the substrate with using the photoresist film as an ion implantation mask (not illustrated). As a result, a second portion E12 of the first conductor film E1 achieves the state in which the portion contains the p-type impurity. The step in which the ion implantation D04 of the n-type impurity into the first portion E11 is carried out before carrying out the ion implantation of the p-type impurity into the second portion E12 has been described above; however, the order of the steps can be opposite.

Through the above-described steps, the first conductor film E1 has the first portion E11 containing the n-type impurity and the second portion E12 containing the p-type impurity. The first portion E11 and the second portion E12 containing the impurities of the opposite polarities are arranged to be adjacent to each other and compose the first conductor film E1, which will later serve as a peripheral gate electrode Gp.

Next, as shown in FIG. 35, the first conductor film E1 of the peripheral circuit region Rp is processed, thereby forming the peripheral gate electrode Gp having the mutually adjacent first portion E11 and second portion E12. Thereafter, the first insulating film I1 of the peripheral circuit region Rp is processed, thereby forming a peripheral gate insulating film Ip provided between the silicon substrate 1 and the peripheral gate electrode Gp. Herein, the peripheral gate electrode Gp and the peripheral gate insulating film Ip are formed by forming an etching mask having a desired gate pattern by a photoresist film or the like (not shown) and sequentially subjecting the first conductor film E1 and the first insulating film I1 to anisotropic etching with using the photoresist film as an ion implantation mask.

Subsequently, a photoresist film 9 is formed in the memory region Rm of the silicon substrate 1, and ion implantation D05 similar to the above-described ion implantation D02 of FIG. 22 is carried out, thereby forming extension regions “exn” which are arranged at portions below and lateral to the peripheral gate electrode Gp. Then, thermal treatment is carried out, for example, at 950° C. for 120 seconds by RTA for activation and diffusion of the impurity ions contained in the gate electrodes, the memory source/drain regions SDm, and the extension regions exn. As a result, depletion in the gate electrodes can be prevented. This thermal treatment is carried out at a lower temperature or shorter time than the thermal treatment carried out for the first silicon oxide film IS1 which has been described above in FIG. 32. In the peripheral circuit region Rp, an n-type impurity is implanted into the extension regions exn of the region in which the n-type MIS transistor is to be formed, and a p-type impurity is implanted into the extension regions (not shown) of the region in which the p-type MIS transistor is to be formed.

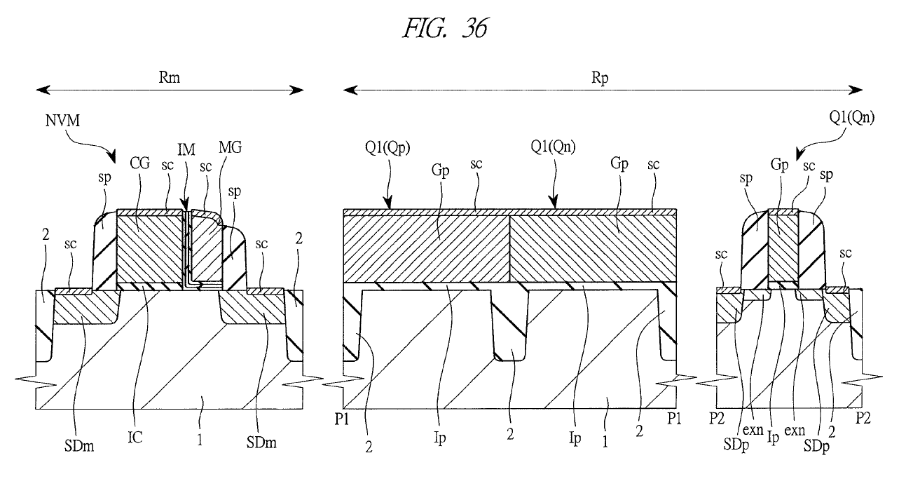

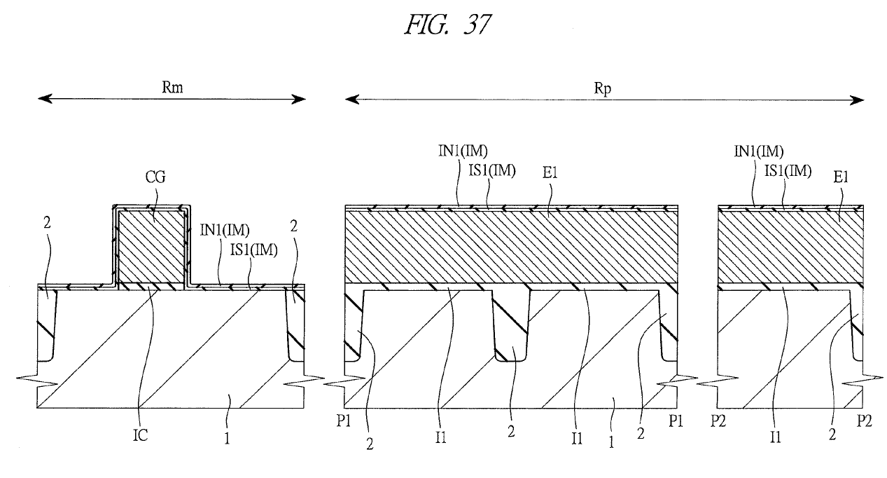

Next, as illustrated in FIG. 36, sidewall spacers sp are formed by a step that is similar to that of above-described FIG. 26. Then, in the state in which the memory region Rm is covered by a photoresist film, the peripheral circuit region Rp of the silicon substrate 1 is subjected to ion implantation that is similar to the above-described ion implantation D01 of FIG. 21 or the ion implantation D03 of FIG. 31. As a result, peripheral source/drain regions SDp are formed. Herein, an n-type impurity is implanted into the region in which the n-type MIS transistor is to be formed, and a p-type impurity is implanted into the region in which the p-type MIS transistor is to be formed. Thereafter, for example, thermal treatment is carried out at for 5 seconds by RTA, thereby activating the peripheral source/drain regions SDp and other impurity-introduced regions. This thermal treatment is carried out at a lower temperature or shorter time than the above-described thermal treatment carried out for the first silicon oxide film IS1 described in FIG. 32. In a subsequent step, a metal silicide layer sc is formed by a step that is similar to the above-described step of FIG. 26.

In the foregoing, in the manufacturing method of the second embodiment and the structure formed by the method, it has been assumed that the part similar to that of the above-described first embodiment has the similar effects which have been described in detail in the above-described first embodiment, and repetitive descriptions thereof will be omitted herein.

Hereinafter, the functions and effects provided by the manufacturing method of the semiconductor device of the second embodiment and the semiconductor device of the second embodiment formed by the manufacturing method will be explained in detail.

As it can be understood from the above-described descriptions with reference to FIG. 27 and FIG. 34, when the MIS transistors Q1 (Qn, Qp) having different polarities share the peripheral gate electrode Gp in the SRAM circuit, there is a boundary between the region that contains a large amount of the donor impurity (first portion E11) and the region that contains a large amount of the acceptor impurity (second portion E12). In this state, for example, when the thermal treatment step at a comparatively high temperature described in the above-described step of FIG. 32 is carried out, the impurities may be cancelled out by interdiffusion. Therefore, it is not desirable to carry out the thermal treatment step at a high temperature after subjecting the peripheral gate electrode Gp to the ion implantation of the different polarities. Meanwhile, it is desirable to carry out ion implantation while the state of the first conductor film E1 is maintained (before carrying out shape processing) since it is difficult to carry out the ion implantation after subjecting the peripheral gate electrode Gp to shape processing.

From this viewpoint, for example, when the peripheral gate electrode Gp is subjected to shape processing at the same time as the select gate electrode CG (above-described step of FIG. 17) like the manufacturing method of the above-described first embodiment, the peripheral gate electrode Gp is necessary to be subjected to ion implantation before that. Therefore, in the later step in which the charge accumulating film IM is formed (above-described step of FIG. 23), the first silicon oxide film IS1 cannot be readily subjected to the thermal treatment step like that described in above-described FIG. 32 of the present second embodiment. This is for the reason that, if the thermal treatment is carried out at this timing, the impurities implanted into the peripheral gate electrode Gp and having the different polarities can be interdiffused in the vicinity of the boundary.

Regarding this matter, in the manufacturing method of the second embodiment, the first conductor film E1 of the peripheral circuit region Rp is not processed in the step of processing the first conductor film E1 in the memory region Rm to form the select gate electrode CG. Then, the impurity ions having the different polarities are implanted into the first conductor film E1 of the peripheral circuit region Rp at least after formation of the charge accumulating film IM is finished and the first silicon oxide film IS1 is subjected to thermal treatment. According to this manner, the non-volatile memory NVM and the peripheral circuit element can be formed without cancelling out the implanted impurities by interdiffusion. As a result, the characteristics of the semiconductor device having the non-volatile memory can be further improved.

In the manufacturing method of the second embodiment, the ion implantation D05 for forming the extension regions exn of the peripheral circuit region Rp and the ion implantation for forming peripheral source/drain regions SDp etc. are necessary to be carried out after the charge accumulating film IM is formed. However, since the memory region Rm is covered by the photoresist film 9, for example, like in above-described FIG. 35 while the ion implantation is being carried out, the charge accumulating film IM is not readily damaged by the ion implantation.

In the above-described manner, the non-volatile memory NVM can be formed in the memory region Rm of the silicon substrate 1, and the MIS transistors Q1 can be formed in the peripheral circuit region Rp by the manufacturing method of the present second embodiment. Particularly, according to the manufacturing method of the present second embodiment, in the manufacturing method of the semiconductor device in which the non-volatile memory NVM is formed by the steps that do not readily damage the charge accumulating film IM, furthermore, the thermal treatments that can further improve the electric charge retention characteristic of the charge accumulating film IM can be carried out in the order of the steps that does not readily cause interdiffusion of the impurities in the peripheral gate electrode Gp. As a result, the characteristics of the semiconductor device having the non-volatile memory can be further improved.

### Third Embodiment

A manufacturing method of a semiconductor device of a third embodiment and the semiconductor device of the third embodiment formed by the manufacturing method will be described with reference to FIG. 37 to FIG. 43. In FIG. 37 to FIG. 43, as same as the above-described second embodiment, cross-sectional views of main parts of the memory region Rm are illustrated on the left, cross-sectional views viewed in the direction of the arrows along the line P1-P1 in the above-described SRAM circuit of FIG. 27 in the peripheral circuit region Rp are illustrated in the center, and cross-sectional views viewed in the direction of the arrows along the line P2-P2 are illustrated on the right side. Note that, in the manufacturing method of the third embodiment which will be described below and the structure of the semiconductor device formed by the method, the manufacturing method similar to that described in the above-described first and second embodiments and the structure similar to that of the semiconductor device formed by the methods of the first and second embodiments have the effects similar to the first and second embodiments, and repetitive descriptions will be omitted herein unless otherwise stated particularly.

In the manufacturing method of the third embodiment, first, steps similar to those up to the step described with reference to FIG. 28 of the above-described second embodiment are carried out.

Next, as illustrated in FIG. 37, a first silicon oxide film IS1 and a first silicon nitride film IN1 are sequentially formed so as to integrally cover the main surface of the silicon substrate 1 in the memory region Rm and the select gate electrode CG. Both of them are formed in the same manner as the above-described step of FIG. 32. They are components of the charge accumulating film IM (for example, described in the above-described step of FIG. 32). Moreover, the above-described thermal treatment with respect to the first silicon oxide film IS1, which has been described with reference to FIG. 32 in the manufacturing method of the above-described second embodiment is similarly carried out also in the manufacturing method of the third embodiment.

In this manner, in the manufacturing method of the third embodiment, the first silicon oxide film IS1 and the first silicon nitride film IN1 among the stacked films composing the charge accumulating film IM are formed at the point of this step, and the process proceeds to a next step without forming the second silicon oxide film IS2 (for example, described in above-described FIG. 32) at the upper part. At this point, the manufacturing method of the third embodiment is different from that of the above-described first or second embodiment in which the charge accumulating film IM is formed by sequentially forming the stacked film of three layers. The effects of forming the charge accumulating film IM in the above-described manner in the manufacturing method of the third embodiment will be explained later in detail. Note that, in this step, if any predetermined photoresist film or the like is not formed in the peripheral circuit region Rp, the peripheral circuit region Rp is also subjected to a similar step, and the first silicon oxide film IS1 and the first silicon nitride film IN1 are formed so as to cover the first conductor film E1.

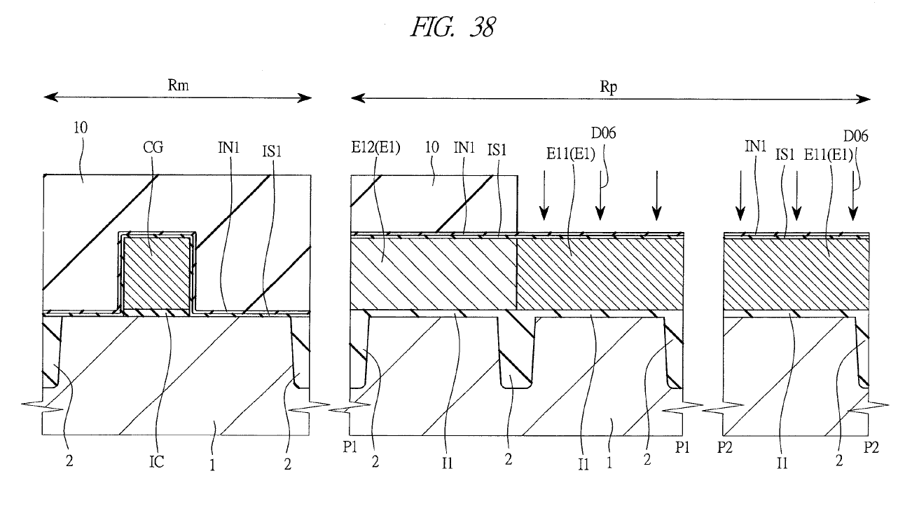

Next, as shown in FIG. 38, by a step similar to that of above-described FIG. 34, in the peripheral circuit region Rp, an impurity to obtain the n-type is implanted into the first portion E11 in the first conductor film E1. In order to carry out this step, a photoresist film 10 similar to the above-described photoresist film 8 of FIG. 34 is formed, and ion implantation D06 similar to the above-described ion implantation D04 of FIG. 34 is carried out. At this point, while the first silicon oxide film IS1 and the first silicon nitride film IN1 are formed on the first conductor film E1, in the manufacturing method of the third embodiment, the ion implantation D06 is carried out so that the impurity penetrates through the first silicon oxide film IS1 and the first silicon nitride film IN1. As a result, the first portion E11 of the first conductor film E1 becomes the state of containing the n-type impurity.

Subsequently, by a step similar to that of above-described FIG. 34, an impurity to obtain the p-type is implanted into a second portion E12 of the first conductor film E1 so that the impurity penetrates through the first silicon oxide film IS1 and the first silicon nitride film IN1. As a result, the second portion E12 of the first conductor film E1 achieves the state of containing the p-type impurity. Note that, in the above description, the step in which the ion implantation D06 of the n-type impurity into the first portion E11 is carried out before the ion implantation of the p-type impurity into the second portion E12 has been described. However, the order thereof can be opposite.

In the above-described manner, the first conductor film E1 having the first portion E11 and the second portion E12 having a similar constitution as above-described FIG. 34 are formed in the peripheral circuit region Rp of the silicon substrate 1. As described above, in the manufacturing method of the third embodiment, the implantation of the opposite conduction type impurities into the first portion E11 and the second portion E12 of the first conductor film E1 and a step subsequent to that are carried out after the thermal treatment step of the first silicon oxide film IS1. This exerts the effects similar to those of the manufacturing method of the above-described second embodiment. More specifically, the manufacturing method which does not readily cause interdiffusion of the impurities of opposite conduction types between the first portion E11 and the second portion E12 which are mutually adjacent in the first conductor film E1 can be obtained.

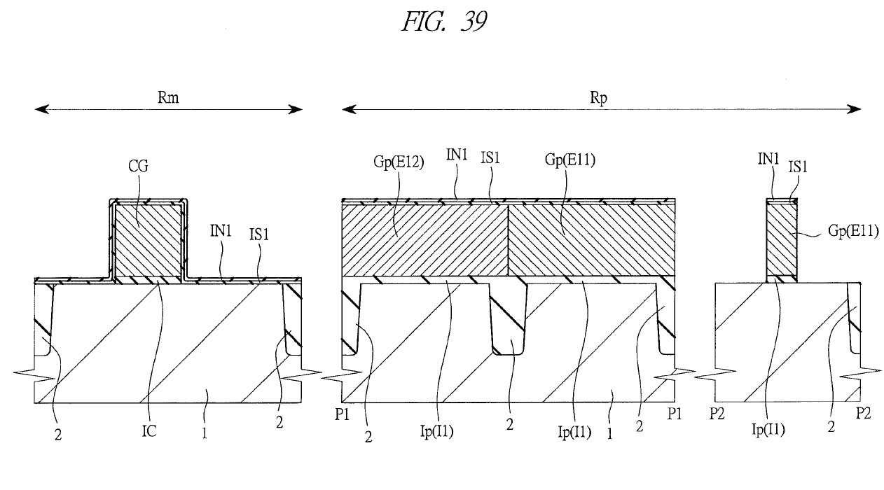

Next, as shown in FIG. 39, as same as the above-described step of FIG. 35, the first conductor film E1 of the peripheral circuit region Rp is processed, thereby forming the peripheral gate electrode Gp having the first portion E11 and the second portion E12 which are adjacent to each other. Thereafter, in order to activate the impurity ions contained in the gate electrodes, for example, thermal treatment is carried out at 9500C for 120 seconds by RTA. As a result, depletion in the gate electrodes can be prevented. This thermal treatment is carried out at a lower temperature or shorter time than the thermal treatment carried out for the first silicon oxide film IS1 described in above-described FIG. 37.

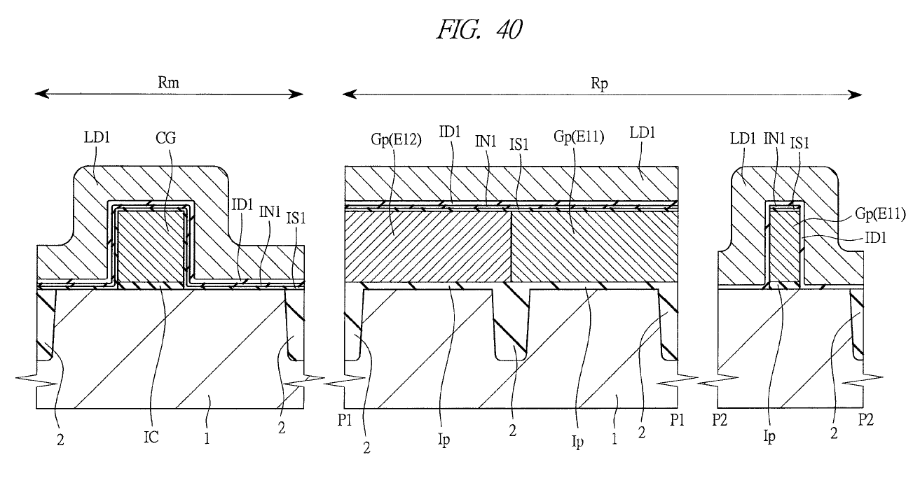

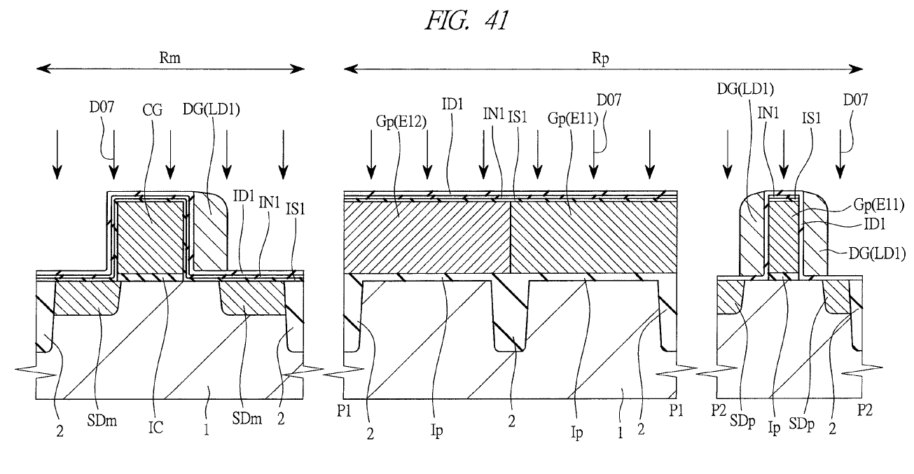

Next, as illustrated in FIG. 40, a dummy insulating film ID1 is formed so as to cover the first silicon nitride film IN1 of the memory region Rm. In this step, an insulating film mainly formed of silicon oxide and having a thickness of about 10 nm is deposited as the dummy insulating film ID1 by a low-temperature-specification CVD method using ozone (O₃) and TEOS (Tetra Ethyl Ortho Silicate) as raw materials. The effects of forming the dummy insulating film ID1 in this step, forming the dummy insulating film ID1 by the above-described formation method, forming the dummy insulating film ID1 to have the above-described thickness, etc. in the manufacturing method of the third embodiment will be explained later in detail.

Note that the formation of the dummy insulating film ID1 can be carried out after the step of forming the first silicon oxide film IS1 and the first silicon nitride film IN1 described with reference to above-described FIG. 37 and before the step of forming the photoresist film 10 described with reference to above-described FIG. 38. As a result, the characteristics of the memory are improved because the first silicon nitride film IN1 is not exposed in the step of removing the photoresist film 10.

Subsequently, a first dummy film LD1 similar to that of above-described FIG. 29 is formed so as to cover the first silicon nitride film IN1 via the dummy insulating film ID1.

Note that, since a photoresist film or the like is not formed in the peripheral circuit region Rp during the above-described steps, elements similar to those described above are formed therein. More specifically, in the peripheral circuit region Rp, the dummy insulating film ID1 and the first dummy film LD1 are formed so as to cover the silicon substrate 1 and the peripheral gate electrode Gp.

Next, as shown in FIG. 41, as same as the above-described steps of FIG. 29 and FIG. 30, dummy gates DG are formed. In the manufacturing method of the third embodiment, the dummy gates DG are formed so as to be arranged on one of the sidewalls of the select gate electrode CG and arranged to be adjacent to both sidewalls of the peripheral gate electrode Gp via the first silicon oxide film IS1, the first silicon nitride film IN1, and the dummy insulating film ID1.

Thereafter, ion implantation D07 similar to the above-described ion implantation D03 of FIG. 31 is carried out. In this step, in the memory region Rm, the select gate electrode CG and the dummy gate DG serve as an ion implantation mask, and memory source/drain regions SDm similar to those of above-described FIG. 31 are formed. In the peripheral circuit region Rp, the peripheral gate electrode Gp and the dummy gates DG serve as an ion implantation mask, and peripheral source/drain regions SDp similar to those of above-described FIG. 21 are formed. Note that, in the peripheral circuit region Rp, an n-type impurity is implanted into the region in which the n-type MIS transistor is to be formed, and a p-type impurity is implanted into the region in which the p-type MIS transistor is to be formed.

At this point, the first silicon oxide film IS1, the first silicon nitride film IN1, and the dummy insulating film ID1 are formed on a sidewall of the select gate electrode CG which is not adjacent to the dummy gate DG among the sidewalls of the select gate electrode CG which functions as the ion implantation mask. Therefore, offset can be caused by the amount corresponding to the film thicknesses of the films in planar view between the select gate electrode CG and the memory source/drain region SDm. In order to compensate for that, the ion implantation D07 may be angled to be oblique implantation instead of vertical implantation with respect to the silicon substrate 1. Also, the offset can be eliminated by controlling the diffusion distance by the temperature and time of later RTA.

Next, by a method similar to the above-described method described with reference to FIG. 21, the dummy gates DG of the memory region Rm and the peripheral circuit region Rp of the silicon substrate 1 are removed.

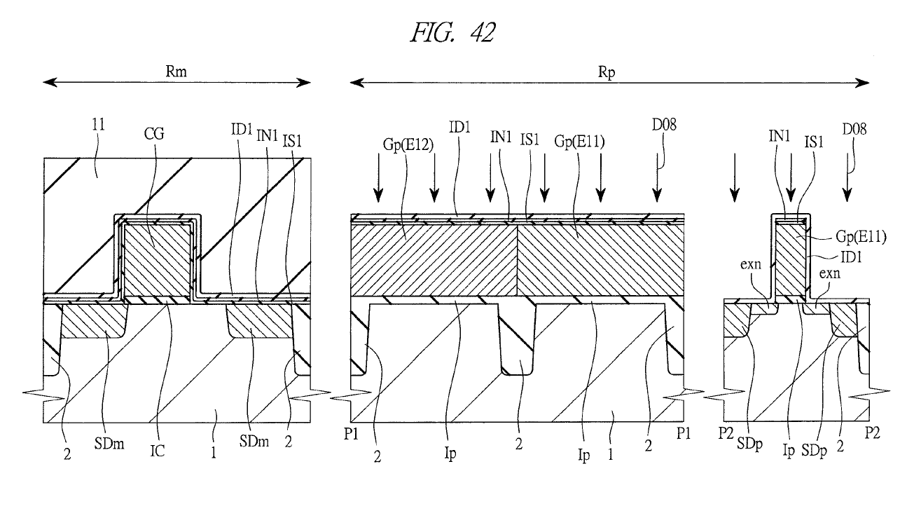

Next, as illustrated in FIG. 42, as same as above-described FIG. 35, extension regions exn are formed in the peripheral circuit region Rp. More specifically, the memory region Rm is covered by a photoresist film 11, and the peripheral circuit region Rp is subjected to ion implantation D08 similar to the above-described ion implantation D05 of FIG. 35. In this step, the peripheral gate electrode Gp serves as an ion implantation mask, and the extension regions exn are formed at portions below and lateral to the peripheral gate electrode Gp. Note that, in the peripheral circuit region Rp, the n-type impurity is implanted into the region in which the n-type MIS transistor is to be formed, and the p-type impurity is implanted into the region in which the p-type MIS transistor is to be formed.

At this point, the sidewalls of the peripheral gate electrode Gp, which functions as the ion implantation mask, are covered by the dummy insulating film ID1. Therefore, offset can be caused by the amount corresponding to the film thickness of the dummy insulating film ID1 in a planer view between the peripheral gate electrode Gp and the extension region exn. In order to compensate for that, the ion implantation D08 may be angled to be oblique implantation instead of vertical implantation with respect to the silicon substrate 1. The offset can be also eliminated by controlling the diffusion distance by the temperature and time of later RTA.

In a subsequent step, the dummy insulating film ID1 of the memory region Rm and the peripheral circuit region Rp is removed by, for example, isotropic etching.

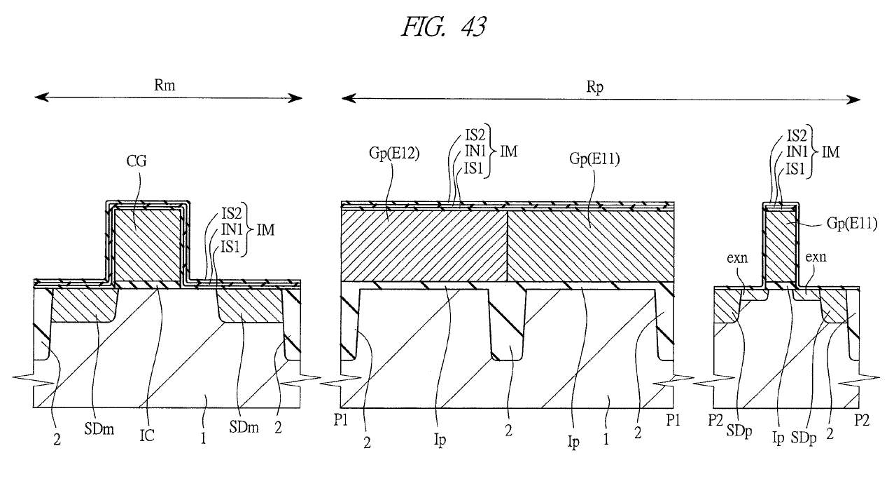

Next, as illustrated in FIG. 43, in the memory region Rm, a second silicon oxide film IS2 is formed so as to cover the first silicon nitride film IN1. This is formed by a method similar to that of the above-described second silicon oxide film IS2 of FIG. 32. As a result of this step, the charge accumulating film IM formed of the first silicon oxide film IS1, the first silicon nitride film IN1, and the second silicon oxide film IS2 is formed in the memory region Rm of the silicon substrate 1 so as to cover the select gate electrode CG and the main surface.

Note that, since a special photoresist film or the like is not formed in the peripheral circuit region Rp in this step, the second silicon oxide film IS2 is formed also in the peripheral circuit region Rp so as to cover the peripheral gate electrode Gp and the main surface.

In subsequent steps, a memory gate electrode MG, sidewall spacers sp, and a metal silicide layer sc are formed by steps similar to those of above-described FIG. 24 to FIG. 26.

Hereinafter, the functions and effects provided by the manufacturing method of the semiconductor device of the third embodiment and the semiconductor device of the third embodiment formed by the manufacturing method will be explained in detail.

As described above, according to the manufacturing method of the third embodiment, the ion implantation of the impurities of the opposite conduction types into the first conductor film E1 is carried out after the thermal treatment with respect to the first silicon oxide film IS1. As a result, in the manufacturing method, particularly, interdiffusion of the impurities of the opposite conduction types caused by thermal treatment at a high temperature does not readily occurs. This is the effect similar to that provided by the above-described second embodiment.

Herein, in the peripheral circuit region Rp, forming the peripheral gate electrode Gp by processing the first conductor film E1 cannot be carried out before implanting the impurity ions of the opposite conduction types into the first portion E11 and the second portion E12 of the first conductor film E1. This is for the reason that it is difficult to implant the impurity ions into the peripheral gate electrode Gp that is obtained by processing the first conductor film E1 and is not in the state of a film. Therefore, in the manufacturing method of the above-described second embodiment, the ion implantation into the first conductor film E1 in the peripheral circuit region Rp and the processing steps thereafter are carried out at least after the step of forming the charge accumulating film IM having the first silicon oxide film IS1 which requires the thermal treatment.

On the other hand, in the manufacturing method of the third embodiment, the first silicon oxide film IS1 which requires the thermal treatment is formed before the step of forming the dummy gates DG. Therefore, after the thermal treatment with respect to the first silicon oxide film IS1 is finished, and before starting the step of forming the dummy gates DG, the first conductor film E1 can be subjected to ion implantation and processing, thereby forming the peripheral gate electrode Gp in the peripheral circuit region Rp. Thereafter, if the first conductor film E1 has been processed and already has the shape of the peripheral gate electrode Gp, a diffusion layer (peripheral source/drain regions, etc.) at portions below and lateral to the peripheral gate electrode Gp can be formed in this state at any timing thereafter. Thus, in the manner of the manufacturing method of the third embodiment, the peripheral source/drain regions SDp can be formed at the same time by the ion implantation D07 for forming the memory source/drain regions SDm. Then, the step of forming the non-volatile memory NVM in the memory region Rm and the step of forming the peripheral circuit elements (for example, MIS transistors Q1) in the peripheral circuit region Rp subsequent to the ion implantation D01 can be shared.

More specifically, as described with reference to above-described FIG. 41, the step of forming the dummy gates DG, the step of forming the memory source/drain regions SDm and the peripheral source/drain regions SDp by carrying out the same ion implantation D07, and the step of removing the dummy gates DG can be shared. Sharing the steps carried out for the memory region Rm and the steps carried out for the peripheral circuit region Rp has the effects similar to the effects explained in the above-described first embodiment.

In this manner, according to the manufacturing method of the present third embodiment, in the manufacturing method of the semiconductor device in which the non-volatile memory NVM is formed by the steps that do not readily damages the charge accumulating film IM, furthermore, the thermal treatment capable of improving the charge retention property of the charge accumulating film IM can be carried out in the order of the steps that does not readily cause mutual diffusion of the impurities in the peripheral gate electrode Gp. Moreover, the steps carried out for the memory region Rm and the peripheral circuit region Rp can be shared, so that the manufacturing steps of the semiconductor device having the non-volatile memory NVM can be simplified. As a result, the characteristics of the semiconductor device having the non-volatile memory can be improved.

Further, in the manufacturing steps of the third embodiment, the ion implantation D07 for forming the memory source/drain regions SDm is carried out after the first silicon oxide film IS1 and the first silicon nitride film IN1 serving as constituent elements of the charge accumulating film IM are formed. In this step, there is a risk of damage introduced into the elements composing the charge accumulating film IM caused by the ion implantation D07. Herein, the damage caused by the ion implantation is most readily introduced into the second silicon oxide film IS2 positioned in the uppermost layer of the charge accumulating film IM. From this viewpoint, in the manufacturing method of the third embodiment, the introduction of damage into the second silicon oxide film IS2 can be avoided because the second silicon oxide film IS2 of the upper part is formed after the ion implantation D07 is carried out. As a result, the characteristics of the semiconductor device having the non-volatile memory can be further improved.

Moreover, according to the manufacturing method of the third embodiment, the dummy insulating film ID1 is formed so as to cover the first silicon oxide film IS1 and the first silicon nitride film IN1. Therefore, the damage caused by the ion implantation D07 is introduced into the dummy insulating film ID1. Then, the dummy insulating film ID1 is removed in a later step and does not serve as a constituent element of the charge accumulating film IM. Therefore, according to the manufacturing method of the third embodiment, the damage caused by the ion implantation D07 onto the charge accumulating film IM can be further reduced. As a result, the characteristics of the semiconductor device having the non-volatile memory can be further improved.

From this viewpoint, it is more preferable to form the film thickness of the dummy insulating film ID1 to be thicker than the second silicon oxide film IS2, which is formed later as a constituent element of the charge accumulating film IM. As a result, the influence of the ion implantation D07 introduced into the first silicon nitride film IN1, the first silicon oxide film IS1, etc. below the dummy insulating film ID1 can be further reduced. As a result, the characteristics of the semiconductor device having the non-volatile memory can be further improved.

In consideration of the object to reduce the damage caused by the ion implantation D07 onto the charge accumulating film IM, the material of the dummy insulating film ID1 is not limited to the silicon oxide film, which is formed by the above-described method described in FIG. 40. Meanwhile, for the following reason, it is more preferable to use, as the dummy insulating film ID1, a material having an etching rate with respect to predetermined etching that is different from the etching rate of the first dummy film LD1, which serves as the dummy gates DG, in the manufacturing method of the third embodiment. The reason thereof is that the dummy gates DG are formed by etching back the first dummy film LD1 and that the dummy insulating film ID1, which is a lower layer of the first dummy film LD1, serves as an etching stopper film of the dummy gate DG. Therefore, when a film having a high selectivity against the dummy gates DG with respect to the etch back (anisotropic etching) is used as the dummy insulating film ID1, the dummy gates DG can be formed without causing damage of over etching or the like onto the first silicon nitride film IN1, the first silicon oxide film IS1, etc. of further lower layers. As a result, the characteristics of the semiconductor device having the non-volatile memory can be further improved.

Furthermore, in the manufacturing method of the third embodiment, it is more preferable to form an insulating film mainly formed of silicon oxide as the dummy insulating film ID1 by the low-temperature-specification CVD method using ozone and TEOS as raw materials. The reason therefor is described below.

The dummy insulating film ID1 is not a constituent element of the charge accumulating film IM and necessary to be removed in a later step by isotropic etching or the like. Herein, the first silicon nitride film IN1, which has a comparatively thin thickness of about 5 nm and is also a constituent element of the charge accumulating film IM, serves as a base of the dummy insulating film ID1. Therefore, in order to normally remove the dummy insulating film ID1, it is more preferable that the selectivity thereof with respect to isotropic etching is higher than that of the first silicon nitride film IN1. Furthermore, in order to prevent the etching from damaging the thin first silicon nitride film IN1 as much as possible, it is more preferable that the dummy insulating film ID1 is a film that can be readily removed by isotropic etching. The manufacturing method of the third embodiment describes the step in which a silicon oxide film formed in the above-described method is used as the dummy insulating film ID1 which satisfies these conditions. In this manner, the damage caused on the charge accumulating film IM can be further reduced by the step which uses the dummy insulating film ID1, which is effective in the above-described manner. As a result, the characteristics of the semiconductor device having the non-volatile memory can be further improved.

The manufacturing method of the semiconductor device of the third embodiment and the semiconductor device of the third embodiment formed by the manufacturing method have similar effects in the constitution that is similar to that of the above-described first or second embodiment, in addition to the effects explained in detail in the above descriptions.

### Fourth Embodiment

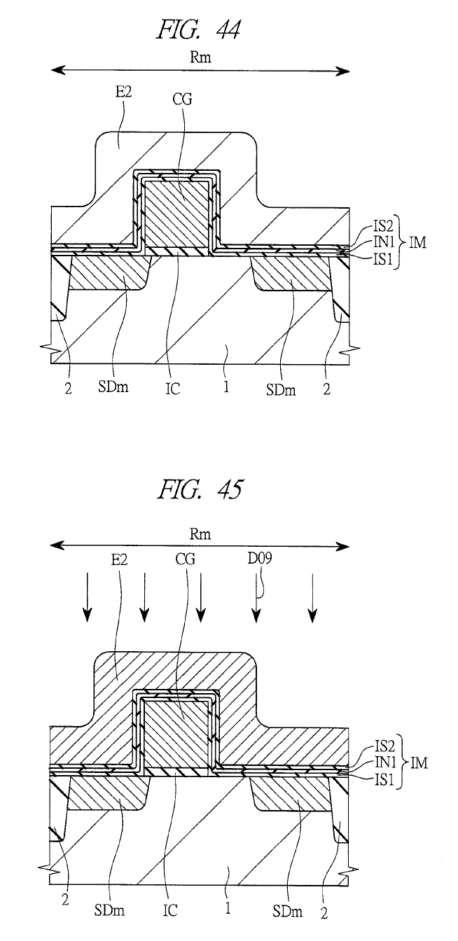

A manufacturing method of a semiconductor device of a fourth embodiment and the semiconductor device of the fourth embodiment formed by the manufacturing method will be described with reference to FIG. 44 to FIG. 46. The manufacturing method of the fourth embodiment illustrated in FIG. 44 and subsequent drawings illustrate steps subsequent to FIG. 23 of the above-described first embodiment. More specifically, the fourth embodiment describes the steps subsequent to formation of the select gate insulating film IC, the select gate electrode CG, the memory source/drain regions SDm, and the charge accumulating film IM, and describes a step of forming the memory gate electrode MG (for example, described in above-described FIG. 25) and a structure formed by the step. In the drawings, only the cross-sectional views of the memory region Rm of the silicon substrate 1 are illustrated.

As illustrated in FIG. 44, a second conductor film E2 is formed so as to cover the charge accumulating film IM. As the second conductor film E2, for example, a polycrystalline silicon film having a thickness of about 100 nm is deposited by the CVD method or the like. Herein, in the manufacturing method of the fourth embodiment, a polycrystalline silicon film not containing significant impurity ions (undoped) is formed as the second conductor film E2. This point is different from the manufacturing methods of above-described first to third embodiments (for example, see the description of FIG. 24). The effects of this point will be explained later in detail.

Next, as illustrated in FIG. 45, the second conductor film E2 is subjected to ion implantation D09 for implanting impurity ions thereinto. More specifically, when the second conductor film E2 is desired to be the n-type (first conduction type), phosphorous ions are implanted thereinto; and, when the second conductor film is desired to be the p-type (second conduction type), boron ions are implanted thereinto. In this step, the ion implantation D09 is carried out with the acceleration energy that does not let ions reach the charge accumulating film, which has been already formed below the second conductor film E2. More specifically, for example, if the second conductor film E2 is a polycrystalline silicon film having a thickness of about 100 nm, the ion implantation D09 is carried out with the acceleration energy of about 3 keV to 10 keV. In addition, the ion implantation D09 is carried out with a dose amount of about 3×10¹⁵ cm⁻².

In order to make the second conductor film E2 conductive, impurity ions which make the conduction type of either the n-type or the p-type can be implanted by the above-described ion implantation D09.

Thereafter, the impurity implanted into the second conductor film E2 is activated and diffused by carrying out thermal treatment. By this thermal treatment, the impurity implanted by the ion implantation D09 is activated and diffused to the entirety of the second conductor film E2, and the second conductor film E2 becomes conductive. More specifically, for example, the thermal treatment is carried out at 950° C. for about 120 seconds. The effects of enabling conduction of the second conductor film E2 in the above-described manner in the fourth embodiment will be explained later in detail.

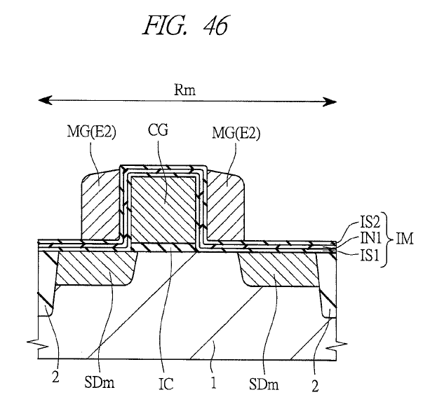

Next, as illustrated in FIG. 46, the second conductor film E2 is processed by etch back, thereby forming memory gate electrodes MG having a similar shape as that in above-described FIG. 24. In subsequent steps, steps similar to those of FIG. 25 and the subsequent drawing of the above-described first embodiment are carried out, thereby forming the non-volatile memory NVM.

Hereinafter, the functions and effects provided by the manufacturing method of the semiconductor device of the fourth embodiment and the semiconductor device of the fourth embodiment formed by the manufacturing method will be explained in detail.

As described above, in the fourth embodiment, as a method of forming the conductive memory gate electrode MG, the second conductor film E2 is made conductive by carrying out the ion implantation D09 after forming the undoped second conductor film E2, instead of forming a polycrystalline silicon film or the like which has been doped in advance. For example, when a polycrystalline silicon film or the like which has been doped in advance is to be formed by the CVD method or the like, the type of ion (dopant) to be contained therein is limited in some cases. On the other hand, when the impurity is implanted into the polycrystalline silicon film by the ion implantation D09 or the like, almost all normally-used dopants can be introduced thereinto. In other words, according to the manufacturing method of the fourth embodiment, various types of impurities can be contained in the second conductor film E2, which later serves as the memory gate electrode MG. This means that the manufacturing method more readily achieves the characteristics which are desired for the memory gate electrode MG.

Furthermore, the ion implantation D09 is not the ion implantation into the silicon substrate 1, but is the ion implantation into the second conductor film E2, which is at an upper layer of the charge accumulating film IM. Therefore, the damage caused by the ion implantation D09 onto the charge accumulating film IM can be avoided when the entire second conductor film E2 is made conductive by carrying out the ion implantation D09 in the manner described above with the acceleration energy adjusted so that the implantation does not reach the charge accumulating film IM, and carrying out diffusion later by the thermal treatment.

In an actual finished form, the charge accumulating film IM below the memory gate electrode MG (second conductor film E2) plays a role of accumulating charges. When the second conductor film E2 is deposited in the above-described step of FIG. 45, the height of the second conductor film E2 at the part where the sidewall-like memory gate electrode MG is going to be formed later is large corresponding to the height of the select gate electrode CG. Therefore, the charge accumulating film IM below the memory gate electrode MG which mainly plays the role of accumulating charges is less readily damaged.

In this manner, according to the manufacturing method of the fourth embodiment, more types of impurities can be introduced into the memory gate electrode MG by the method which is capable of further reducing the damage given to the charge accumulating film IM. As a result, the characteristics of the semiconductor device having the non-volatile memory can be further improved.

Moreover, particularly, the memory gate electrode MG of the p-type can be formed by implanting an impurity to obtain the p-type into the second conductor film E2. Also in the manufacturing method of the present fourth embodiment, as same as the manufacturing methods of the above-described first to third embodiments, the ion implantation of an impurity which obtains the n-type with using the memory gate electrode MG as an ion implantation mask is not carried out. This is the effect of the method in which the ion implantation (for example, the above-described ion implantation D01 of FIG. 21) for forming the n-type memory source/drain regions SDm is carried out by using the dummy gates DG as an ion implantation mask and is carried out before the memory gate electrode MG is formed in the fourth embodiment and the above-described first to third embodiments. Therefore, also in the manufacturing method of the fourth embodiment, the n-type impurity is not introduced into the memory gate electrode MG containing the p-type impurity, and the p-type conduction type of the memory gate electrode MG is not cancelled out.

As described above, according to the manufacturing method of the fourth embodiment, the memory gate electrode MG having the conduction type that is opposite to the conduction type of the memory source/drain regions SDm can be formed. In the semiconductor device having the non-volatile memory NVM, the effects of using the structure having the memory gate electrode MG of such a structure are similar to the effects explained in the above-described first embodiment. As a result, the characteristics of the semiconductor device having the non-volatile memory can be further improved.

In addition, the manufacturing method of the present fourth embodiment having the effects explained above has been explained as the method in which the steps of forming the memory gate electrodes MG in the manufacturing method of the above-described first embodiment are replaced. Similarly, the manufacturing method of the fourth embodiment has similar effects when the method is used as the method in which the steps of forming the memory gate electrodes MG in the manufacturing method of the above-described second or third embodiment are replaced. As a result, the characteristics of the semiconductor device having the non-volatile memory can be further improved.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the n-type and p-type polarities of the semiconductor regions and the conductor films described in the above-described first to fourth embodiments can be opposite, respectively.

Moreover, for example, in the semiconductor devices described in the above-described first to fourth embodiments, the isolation portions 2 have been illustrated to have the STI structure, where the isolation portions 2 define the regions in which a plurality of elements formed on the same substrate are formed. The isolation portions 2 can have a so-called LOCOS (Local Oxidation of Silicon) structure.

The present invention can be used for the industry of semiconductor necessary for information processing in, for example, personal computers, mobile devices, etc.

What is claimed is:

1. A method of manufacturing a semiconductor device comprising a step of forming a non-volatile memory in a first region on a semiconductor substrate, wherein
the step of forming the non-volatile memory includes the steps of:
(a) forming a first conductor film on a main surface of the first region of the semiconductor substrate via a first insulating film;
(b) forming a first gate electrode on the main surface of the semiconductor substrate in the first region via a first gate insulating film by processing the first insulating film and the first conductor film;
(c) forming a dummy gate so that the dummy gate is arranged to be adjacent to either one of a pair of sidewall surfaces of the first gate electrode;
(d) forming first semiconductor regions at portions of the main surface of the semiconductor substrate in the first region, the portions being below and lateral to the first gate electrode and the dummy gate;
(e) removing the dummy gate in the first region of the semiconductor substrate by etching;
(f) forming a charge accumulating film formed of a first silicon oxide film, a first silicon nitride film, and a second silicon oxide film in this order so as to integrally cover the main surface of the semiconductor substrate in the first region and the first gate electrode; and
(g) forming a second gate electrode arranged to be adjacent to the sidewall surface of the first gate electrode, which is the same sidewall surface on which the dummy gate is formed in the step (c) among the pair of the sidewall surfaces of the first gate electrode, and arranged on a portion of the main surface of the semiconductor substrate being above and lateral to the first semiconductor region, the second gate electrode being formed on the sidewall surface and the main surface via the charge accumulating film, wherein,
in the step (d), the first semiconductor regions are formed by subjecting the main surface of the semiconductor substrate in the first region to ion implantation with using the first gate electrode and the dummy gate as an ion implantation mask, and wherein
the step (f) is carried out at least after the step (d).

2. The method of manufacturing the semiconductor device according to claim 1, wherein,
in the step (c), the dummy gate is formed by a same material as the second gate electrode formed in the step (g).

3. The method of manufacturing the semiconductor device according to claim 2, wherein
the step of forming the non-volatile memory further includes, after the step (b) and before the step (c),
(h) a step of forming a protective film so as to integrally cover the main surface of the semiconductor substrate in the first region and the first gate electrode, wherein,
in the step (c), the dummy gate is formed so as to be adjacent to the sidewall surface of the first gate electrode via the protective film; and wherein,
in the step (h), the protective film having an etching rate with respect to predetermined etching different from an etching rate of the dummy gate is formed.

4. The method of manufacturing the semiconductor device according to claim 3, wherein,
in the step (d), the first semiconductor regions of a first conduction type are formed by performing ion implantation of impurity ions which achieve the first conduction type, and wherein,
in the step (g), the second gate electrode of a second conduction type which is an opposite conduction type of the first conduction type is formed.

5. The method of manufacturing the semiconductor device according to claim 4, wherein
the step (g) of forming the second gate electrode includes the steps of:
(g1) forming a second conductor film so as to cover the charge accumulating film formed in the step (f);
(g2) making the second conductor film conductive by subjecting the second conductor film to ion implantation of impurity ions and to thermal treatment; and
(g3) forming the second gate electrode by processing the second conductor film, wherein,
in the step (g2), the ion implantation is carried out with acceleration energy which does not let the impurity ions reach the charge accumulating film at a lower layer of the second conductor film.

6. The method of manufacturing the semiconductor substrate according to claim 5, wherein,
in the step (g2), the second conductor film is made conductive having the second conduction type by carrying out the ion implantation of the impurity ions which achieve the second conduction type and carrying out the thermal treatment.

7. The method of manufacturing the semiconductor device according to claim 6, further including a step of forming a peripheral circuit element in a second region on the semiconductor substrate, wherein
the step of forming the peripheral circuit element includes the steps of:
(i) forming the first conductor film on the main surface of the semiconductor substrate in the second region via the first insulating film;
(j) forming a peripheral gate electrode on the main surface of the semiconductor substrate in the second region via a peripheral gate insulating film by processing the first insulating film and the first conductor film;
(k) forming the dummy gates arranged to be adjacent to sidewall surfaces of the peripheral gate electrode;
(l) forming second semiconductor regions at portions of the main surface of the semiconductor substrate in the second region, the portions being below and lateral to the dummy gate; and
(m) removing the dummy gates of the second region of the semiconductor substrate by etching, and wherein,
in the step (j), the first insulating film and the first conductor film are processed by the same step as the step (b);
in the step (k), the dummy gates are formed by the same step as the step (c);
in the step (l), the second semiconductor regions are formed by subjecting the main surface of the semiconductor substrate in the second region to ion implantation with using the peripheral gate electrode and the dummy gates as an ion implantation mask; and,
in the step (m), the dummy gates are removed by the same step as the step (e).

8. The method of manufacturing the semiconductor device according to claim 7, wherein
the step of forming the peripheral circuit element further includes a step of
(n) forming third semiconductor regions at portions of the main surface of the semiconductor substrate in the second region, the portions being below and lateral to the peripheral gate electrode, and wherein,
in the step (n), the third semiconductor regions are formed by subjecting the main surface of the semiconductor substrate in the second region to ion implantation with using the peripheral gate electrode as an ion implantation mask,
in the step (n), the third semiconductor regions are formed so as to have the same conduction type as the second semiconductor regions formed in the step (l), have a lower impurity concentration than the second semiconductor regions, and be shallower than the second semiconductor regions, and
the step (n) is carried out after the steps (e) and (m) and before the step (f).

9. The method of manufacturing the semiconductor device according to claim 6, wherein,
in the step (f), the charge accumulating film is formed by forming the first silicon oxide film, then subjecting the semiconductor substrate to thermal treatment in a gas atmosphere containing oxygen and nitrogen, and then sequentially forming the first silicon nitride film and the second silicon oxide film, and
the manufacturing method further includes a step of forming a peripheral circuit element in a second region on the semiconductor substrate, wherein
the step of forming the peripheral circuit element includes the steps of:
(i) forming the first conductor film on the main surface of the semiconductor substrate in the second region via the first insulating film;
(j) implanting impurity ions, which achieve the first conduction type, into a first portion of the first conductor film in the second region;
(k) implanting impurity ions, which achieve the second conduction type, into a second portion of the first conductor film in the second region, the second portion being adjacent to the first portion;
(l) forming a peripheral gate electrode having the first portion and the second portion, which are mutually adjacent, by processing the first conductor film in the second region; and
(m) forming a peripheral gate insulating film arranged between the semiconductor substrate and the peripheral gate electrode by processing the first insulating film in the second region, and wherein,
in the step (i), the first insulating film is formed by the same step as the step (a); and
the step (j) and the steps (k) to (m) subsequent to the step (j) are carried out at least after the step (f).

10. A method of manufacturing a semiconductor device comprising a step of forming a non-volatile memory in a first region on a semiconductor substrate and a step of forming a peripheral circuit element in a second region; wherein
the step of forming the non-volatile memory includes the steps of:
(a) forming a first conductor film on a main surface of the semiconductor substrate in the first region via a first insulating film;
(b) forming a first gate electrode on the main surface of the semiconductor substrate in the first region via a first gate insulating film by processing the first insulating film and the first conductor film;
(c) sequentially forming a first silicon oxide film and a first silicon nitride film so as to integrally cover the main surface of the semiconductor substrate in the first region and the first gate electrode;
(d) forming a dummy gate arranged to be adjacent to either one of a pair of sidewall surfaces of the first gate electrode, the dummy gate being formed on the sidewall surface via the first silicon oxide film and the first silicon nitride film;
(e) forming first semiconductor regions at portions on the main surface of the semiconductor substrate in the first region, the portions being below and lateral to the first gate electrode and the dummy gate;
(f) removing the dummy gate in the first region of the semiconductor substrate by etching;
(g) forming a charge accumulating film formed of the first silicon oxide film, the first silicon nitride film, and a second silicon oxide film by forming the second silicon oxide film so as to cover the first silicon nitride film;
(h) forming a second gate electrode arranged to be adjacent to the sidewall surface of the first gate electrode, which is the same sidewall surface on which the dummy gate is formed in the step (c) among the pair of the sidewall surfaces of the first gate electrode, and arranged on a portion of the main surface of the semiconductor substrate, the portion being above and lateral to the first semiconductor region, the second gate electrode being formed on the sidewall surface and the main surface via the charge accumulating film, wherein,
in the step (c), the first silicon nitride film is formed after the thermal treatment is performed in a gas atmosphere containing oxygen and nitrogen after the first silicon oxide film is formed;
in the step (e), the first semiconductor regions are formed by subjecting the main surface of the semiconductor substrate in the first region to ion implantation with using the first gate electrode and the dummy gate as an ion implantation mask, wherein
the step of forming the peripheral circuit element includes the steps of:
(i) forming the first conductor film on the main surface of the semiconductor substrate in the second region via the first insulating film;
(j) implanting impurity ions, which achieve a first conduction type, into a first portion of the first conductor film in the second region;
(k) implanting impurity ions, which achieve a second conduction type, into a second portion of the first conductor film in the second region, the second portion being adjacent to the first portion;
(l) forming a peripheral gate electrode having the first portion and the second portion, which are mutually adjacent, by processing the first conductor film in the second region;
(m) forming a peripheral gate insulating film arranged between the semiconductor substrate and the peripheral gate electrode by processing the first insulating film in the second region;
(n) forming dummy gates so that the dummy gates are arranged to be adjacent to sidewall surfaces of the peripheral gate electrode;
(o) forming second semiconductor regions at portions of the main surface of the semiconductor substrate in the second region, the portions being below and lateral to the dummy gates; and
(p) removing the dummy gates in the second region of the semiconductor substrate by etching, and wherein
the step (j) and the steps (k) to (p) subsequent to the step (j) are carried out at least after the step (c),
in the step (n), the dummy gates are formed by the same step as the step (d),
in the step (o), the second semiconductor regions are formed by subjecting the main surface of the semiconductor substrate in the second region to ion implantation with using the peripheral gate electrode and the dummy gates as an ion implantation mask, and,
in the step (p), the dummy gates are removed by the same step as the step (f).

11. The method of manufacturing the semiconductor device according to claim 10, wherein,
in the step (d), the dummy gate is formed by a same material as the second gate electrode formed in the step (h).

12. The method of manufacturing the semiconductor device according to claim 11, wherein
the step of forming the non-volatile memory further includes, after the step (c) and before the step (d),
(q) a step of forming a dummy insulating film so as to cover the first silicon nitride film in the first region; and
further includes, after the step (f) and before the step (g),
(r) a step of removing the dummy insulating film, and wherein,
in the step (d), the dummy gate is formed to be adjacent to the sidewall surface of the first gate electrode via the first silicon oxide film, the first silicon nitride film, and the dummy insulating film, and,
in the step (q), the dummy insulating film having an etching rate with respect to predetermined etching different from an etching rate of the dummy gate is formed.

13. The method of manufacturing the semiconductor device according to claim 12, wherein,
in the step (q), the dummy insulating film is formed to have a film thickness larger than the second silicon oxide film formed in the later step (g).

14. The method of manufacturing the semiconductor device according to claim 13, wherein,
in the step (q), the dummy insulating film formed of an insulating film mainly made of silicon oxide is formed by a chemical vapor deposition method using ozone and TEOS as raw materials.

15. The method of manufacturing the semiconductor device according to claim 14, wherein,
in the step (e), the first semiconductor regions of a first conduction type are formed by carrying out ion implantation of impurity ions which achieve the first conduction type, and,
in the step (h), the second gate electrode of the second conduction type which is an opposite conduction type of the first conduction type is formed.

16. The method of manufacturing the semiconductor device according to claim 15, wherein
the step (h) of forming the second gate electrode includes the steps of:
(h1) forming a second conductor film so as to cover the charge accumulating film formed in the step (g);
(h2) making the second conductor film conductive by subjecting the second conductor film to ion implantation of impurity ions and to thermal treatment; and
(h3) forming the second gate electrode by processing the second conductor film, and wherein,
in the step (h2), the ion implantation is performed with acceleration energy which does not let the impurity ions reach the charge accumulating film at a lower layer of the second conductor film.

17. The method of manufacturing the semiconductor device according to claim 16, wherein,
in the step (h2), the second conductor film is made conductive having the second conduction type by performing the ion implantation of the impurity ions which achieve the second conduction type and carrying out the thermal treatment.

18. The method of manufacturing the semiconductor device according to claim 17, wherein
the step of forming the peripheral circuit element further includes a step of
(s) forming third semiconductor regions at portions of the main surface of the semiconductor substrate in the second region, the portions being below and lateral to the peripheral gate electrode, wherein,
in the step (s), the third semiconductor regions are formed by subjecting the main surface of the semiconductor substrate in the second region to ion implantation with using the peripheral gate electrode as an ion implantation mask,
in the step (s), the third semiconductor regions are formed to have the same conduction type as the second semiconductor regions formed in the step (o), have a lower impurity concentration than the second semiconductor regions, and be shallower than the second semiconductor regions, and
the step (s) is carried out after the steps (f) and (q) and before the step (g).

19. A semiconductor device comprising a non-volatile memory on a main surface of a semiconductor substrate, wherein
the non-volatile memory includes:
(a) a first gate electrode formed on the main surface of the semiconductor substrate via a first gate insulating film;
(b) a second gate electrode arranged to be adjacent to either one of a pair of sidewall surfaces of the first gate electrode;
(c) a charge accumulating film integrally arranged between the first gate electrode and the second gate electrode and between the semiconductor substrate and the second gate electrode; and
(d) first semiconductor regions formed at portions of the main surface of the semiconductor substrate, the portions being below and lateral to the first gate electrode and the second gate electrode, wherein
the first semiconductor regions contain a first impurity, which achieves a first conduction type, and the second gate electrode contains a second impurity, which achieves a second conduction type which is an opposite conduction type of the first conduction type, and
the concentration of the first impurity in the second gate electrode is lower than the concentration of the first impurity in the first semiconductor regions.
